(19) United States
(12) Patent Application Publication
(10) Pub. No.: US 2015/0145576 A1
(43) Pub. Date: May 28, 2015

(54) SPINTRONIC LOGIC GATES EMPLOYING A GIANT SPIN HALL EFFECT (GSHE) MAGNETIC TUNNEL JUNCTION (MTJ) ELEMENT(S) FOR PERFORMING LOGIC OPERATIONS, AND RELATED SYSTEMS AND METHODS

(71) Applicant: QUALCOMM Incorporated, San Diego, CA (US)

(72) Inventors: Wenqing Wu, San Diego, CA (US); Raghu Sagar Madala, San Diego, CA (US); Kendrick Hoy Leong Yuen, San Diego, CA (US); Karim Arabi, San Diego, CA (US); Robert Philip Gilmore, Poway, CA (US)

(21) Appl. No.: 14/331,688

(22) Filed: Jul. 15, 2014

Related U.S. Application Data
(63) Continuation of application No. 14/330,494, filed on Jul. 14, 2014.
(60) Provisional application No. 61/909,576, filed on Nov. 27, 2013.
(60) Provisional application No. 61/936,396, filed on Feb. 6, 2014.

(51) Int. Cl. H03K 3/45; H03K 19/20; H03K 3/012; H03K 3/037

(52) U.S. Cl. CPC H03K 3/45; H03K 3/037; H03K 19/20; H03K 3/012
USPC 327/187

(57) ABSTRACT

Aspects described herein are related to pipeline circuits employing a Giant Spin Hall Effect (GSHE) magnetic tunnel junction (MTJ) element(s) for performing logical operations. In one aspect, a pipeline circuit is disclosed. The pipeline circuit includes a first pipeline stage and a second pipeline stage. The first pipeline stage is configured to store a first bit set and to generate a first charge current representing the first bit set. The second pipeline stage includes a first GSHE MTJ element. The first GSHE MTJ element is configured to set a first bit state for the first logical operation, and has a first threshold current level. The first GSHE MTJ element is configured to generate a first GSHE spin current in response to the first charge current. In this manner, the first GSHE MTJ element is also configured to perform the first logical operation on the first bit set.

### PRIORITY CLAIMS

The present application claims priority to U.S. Provisional Patent Application Ser. No. 61/909,576 filed on Nov. 27, 2013 and entitled “SPINTRONIC LOGIC GATES FOR PERFORMING LOGIC OPERATIONS, AND RELATED SYSTEMS AND METHODS,” which is incorporated herein by reference in its entirety.

The present application also claims priority to U.S. Provisional Patent Application Ser. No. 61/936,396 filed on Feb. 6, 2014 and entitled “SPINTRONIC LOGIC GATES FOR PERFORMING LOGIC OPERATIONS, AND RELATED SYSTEMS AND METHODS,” which is incorporated herein by reference in its entirety.

The present application is a continuation of and claims priority to U.S. patent application Ser. No. 14/330,494, filed Jul. 14, 2014 and entitled “SPINTRONIC LOGIC GATES EMPLOYING A GIANT SPIN HALL EFFECT (GSHE) MAGNETIC TUNNEL JUNCTION (MTJ) ELEMENT(S) FOR PERFORMING LOGIC OPERATIONS, AND RELATED SYSTEMS AND METHODS,” which is incorporated herein by reference in its entirety.

### BACKGROUND

I. Field of the Disclosure

This disclosure relates generally to logic gates, and related systems and methods, for performing logical operations.

II. Background

Modern electronic devices (e.g., laptops, computers, smart phones, tablets, and the like) are sequential state machines that perform various logical operations using combinations of logic gates. The prevalence of these modern electronic devices is driven in part by the many functions that are now enabled on such devices. Demand for such functions increases processing capability requirements of electronic devices and generates a need for more power-efficient devices. Accordingly, there is increasing pressure to continue miniaturizing logic gates and to reduce their power consumption. Miniaturization of components impacts all aspects of processing circuitry, including transistors and other reactive elements in the processing circuitry, such as metal oxide semiconductors (MOSs). MOS devices generally provide logic gates through combinations of transistors.

Historically, MOS devices have benefited from increasing miniaturization efforts. In the past, such semiconductor miniaturization not only reduced the footprint area occupied by the MOS devices in an integrated circuit (IC), but also reduced the power required to operate such ICs, thereby concurrently improving operating speeds. As the MOS devices were reduced to a nanometer scale (e.g., a ninety (90) nanometer scale), the footprint area occupied by the MOS devices in the IC was reduced, as expected. However, the MOS devices could not operate at an appreciably faster speed, because the mobility of the current mechanism (i.e., electrons or holes) did not also improve linearly, since mobility is a function of the effective mass of the current mechanism, and the effective mass was not changed with miniaturization.

Various techniques have been implemented to attempt to improve the speed with which transistor-based logic gates operate in the nanometer scale. Unfortunately, these techniques are problematic, as transistors have proved difficult to control. Furthermore, transistor-based logic gates continue to present power consumption problems as increases in transistor density have not introduced linear savings in power consumption. Transistor-based logic gates may thus be quickly reaching their design limits, and other types of technologies may be needed to continue the miniaturization of ICs. Thus, an effective technique is needed for creating logic gates and performing logical operations that are better adapted at the nanometer scale and are more power-efficient than current transistor-based technology.

### SUMMARY OF THE DISCLOSURE

Aspects described herein are related to spintronic logic gates employing a Giant Spin Hall Effect (GSHE) magnetic tunnel junction (MTJ) element(s) for performing logical operations. Related systems and methods are also disclosed. More specifically, this disclosure describes aspects of spintronic logic gates that include one or more GSHE MTJ elements configured to perform logical operations. Methods of performing logical operations using one or more GSHE MTJ elements are also disclosed. Additionally, related aspects and methods of fabricating GSHE MTJ elements are disclosed. Since logical operations are performed using GSHE MTJ elements, the spintronic logic gates and the methods for performing logical operations may provide for greater power efficiency than transistor-based logic gates. Also, the spintronic logic gates are capable of being disposed in a relatively compact arrangement within an integrated circuit (IC). For example, the spintronic logic gates disclosed herein may perform logical operations with a smaller number of GSHE MTJ elements than a number of transistors required to perform the same logical operations with transistor-based logic gates. Also, while traditional combinational logic (i.e., logical circuits using transistor-based logic gates) must often employ separate sequential logic (e.g., latches, flip-flops, etc.) to store bit states resulting from the logical operations, the GSHE MTJ elements (i.e., the same elements used to perform the logical operations) examples of the spintronic logic gates disclosed herein may also operate as non-volatile memory to store bit states resulting from the logical operations. Therefore, not only can spintronic logic gates be used to fabricate more compact ICs (e.g., sequential state machines), the spintronic logic gates may also increase processing speeds and simplify IC designs.

In one aspect, a pipeline circuit is disclosed. The pipeline circuit includes a first pipeline stage and a second pipeline stage. The first pipeline stage comprises a first set of one or more MTJ elements configured to store a first bit set comprising one or more bit states for a first logical operation. The first set of one or more MTJ elements is also configured to generate a first charge current representing the first bit set. The second pipeline stage is configured to receive the first charge current and includes a first GSHE MTJ element. The first GSHE MTJ element is configured to set a first bit state for the first logical operation, and has a first threshold current level. The first GSHE MTJ element is configured to generate a first GSHE spin current in response to the first charge current. The first GSHE MTJ element is also configured to perform the first logical operation on the first bit set by setting the first bit state based on whether the first GSHE spin current exceeds the first threshold current level.

In another aspect, a pipeline method is disclosed. The pipeline method includes storing a first bit set comprising one or more bit states for a first logical operation with a first set of one or more MTJ elements within a first pipeline stage. Additionally, the pipeline method includes generating a first charge current representing the first bit set with the first set of one or more MTJ elements. Furthermore, the pipeline method includes receiving the first charge current in a second pipeline stage. The second pipeline stage comprises a first GSHE MTJ element configured to set a first bit state for the first logical operation and having a first threshold current level. Also, the pipeline method includes generating a first GSHE spin current with the first GSHE MTJ element in response to the first charge current. Finally, the pipeline method includes performing the first logical operation on the first bit set with the first GSHE MTJ element by setting the first bit state based on whether the first GSHE spin current exceeds the first threshold current level.

In one aspect, a spintronic logic gate is disclosed which includes a charge current generation circuit and a first GSHE MTJ element. The charge current generation circuit is configured to generate a first charge current representing an input bit set. The input bit set may include one or more input bit states for a first logical operation. The first GSHE MTJ element is configured to set a first logical output bit state for the first logical operation, and has a first threshold current level. The first GSHE MTJ element is configured to generate a first GSHE spin current in response to the first charge current by producing a GSHE that converts the first charge current into the first GSHE spin current. The first GSHE MTJ element includes a GSHE electrode configured to generate the first GSHE spin current in response to the first charge current. The first GSHE MTJ element is also configured to perform the first logical operation on the input bit set by setting the first logical output bit state based on whether the first GSHE spin current exceeds the first threshold current level.

In another aspect, a spintronic logic method is disclosed. The spintronic logic method includes generating a first charge current representing an input bit set comprising one or more input bit states for a first logical operation. The spintronic logic method also includes generating a first GSHE spin current with a GSHE electrode that provides a GSHE in response to the first charge current. Finally, the spintronic logic method includes performing the first logical operation on the input bit set by setting a first logical output bit state based on whether the first GSHE spin current exceeds a first threshold current level.

### BRIEF DESCRIPTION OF THE FIGURES

FIG. 1 illustrates a cross-sectional view of one aspect of a Giant Spin Hall Effect (GSHE) magnetic tunnel junction (MTJ) element that may be used in a spintronic logic gate to perform logical operations;

FIG. 2A illustrates a top-down view of one exemplary aspect of a GSHE electrode and a free layer of the GSHE MTJ element shown in FIG. 1;

FIG. 2B illustrates a top-down view of another exemplary aspect of a GSHE electrode and a free layer of the GSHE MTJ element shown in FIG. 1;

FIG. 3 is a perspective view of a GSHE electrode of the GSHE MTJ element shown in FIG. 1;

FIG. 4 illustrates one aspect of a free layer and a GSHE electrode of the GSHE MTJ element shown in FIG. 1;

FIG. 5 is a visual illustration of an operative symbol used to represent the GSHE MTJ element shown in FIG. 1;

FIG. 6A illustrates one example of a GSHE MTJ element, which is one aspect of the GSHE MTJ element shown in FIG. 1;

FIG. 6B illustrates another example of a GSHE MTJ element, which is another aspect of the GSHE MTJ element shown in FIG. 1;

FIG. 6C illustrates yet another example of a GSHE MTJ element, which is yet another aspect of the GSHE MTJ element shown in FIG. 1;

FIG. 7 is a graph that illustrates one aspect of a Stoner-Wohlfarth Switching Astroid that indicates a threshold current level of the GSHE MTJ element shown in FIG. 1;

FIG. 8 illustrates one aspect of a spintronic logic gate which may be utilized to perform logical operations;

FIG. 9 illustrates a group of truth tables representing the logical operations performed by the spintronic logic gate shown in FIG. 8;

FIG. 10 illustrates a timing diagram representing control states of control signals used to synchronize and preset the spintronic logic gate shown in FIG. 8;

FIG. 11 illustrates another aspect of a spintronic logic gate which may be utilized to perform logical operations;

FIG. 12 illustrates yet another aspect of a spintronic logic gate which may be utilized to perform logical operations;

FIG. 13 illustrates yet another aspect of a spintronic logic gate which may be utilized to perform logical operations;

FIG. 14A illustrates one aspect of a pipeline circuit that includes pipeline stages with MTJ elements configured to perform buffering operations and inversion operations;

FIG. 14B illustrates a timing diagram representing control states of control signals used to synchronize and preset the pipeline circuit shown in FIG. 14A;

FIG. 15A illustrates another aspect of a pipeline circuit that includes pipeline stages with MTJ elements configured to perform AND operations, NAND operations, and NOR operations;

FIG. 15B illustrates a timing diagram representing control states of control signals used to synchronize and preset the pipeline circuit shown in FIG. 15A;

FIG. 16A illustrates still another aspect of a pipeline circuit that includes pipeline stages with MTJ elements configured to perform AND operations, OR operations, NAND operations, and NOR operations;

FIG. 16B illustrates a timing diagram representing control states of control signals used to synchronize and preset the pipeline circuit shown in FIG. 16A;

FIG. 17A illustrates yet another aspect of a pipeline circuit that includes pipeline stages with MTJ elements configured to perform AND operations, OR operations, NAND operations, and NOR operations;

FIG. 17B illustrates a timing diagram representing control states of control signals used to synchronize and preset the pipeline circuit shown in FIG. 17A; and

FIG. 18 is a block diagram of an exemplary processor-based system that can include the GSHE MTJ element, the spintronic logic gates, and the pipeline circuits of FIGS. 1, 8, 11, 12, 13, 14A, 15A, 16A, and 17A.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects described herein are related to spintronic logic gates employing a Giant Spin Hall Effect (GSHE) magnetic tunnel junction (MTJ) element(s) for performing logical operations. Related systems and methods are also disclosed. More specifically, this disclosure describes aspects of spintronic logic gates that include one or more GSHE MTJ elements configured to perform logical operations. Methods of performing logical operations using one or more GSHE MTJ elements are also disclosed. Additionally, related aspects and methods of fabricating GSHE MTJ elements are disclosed. Since logical operations are performed using GSHE MTJ elements, the spintronic logic gates and the methods for performing logical operations may provide for greater power efficiency than transistor-based logic gates. Also, the spintronic logic gates are capable of being disposed in a relatively compact arrangement within an integrated circuit (IC). For example, the spintronic logic gates disclosed herein may perform logical operations with a smaller number of GSHE MTJ elements than a number of transistors required to perform the same logical operations with transistor-based logic gates. Also, while traditional combinational logic (i.e., logical circuits using transistor-based logic gates) must often employ separate sequential logic (e.g., latches, flip-flops, etc.) to store bit states resulting from the logical operations, the GSHE MTJ elements (i.e., the same elements used to perform the logical operations) examples of the spintronic logic gates disclosed herein may also operate as non-volatile memory to store bit states resulting from the logical operations. Therefore, not only can spintronic logic gates be used to fabricate more compact ICs (e.g., sequential state machines), the spintronic logic gates may also increase processing speeds and simplify IC designs.

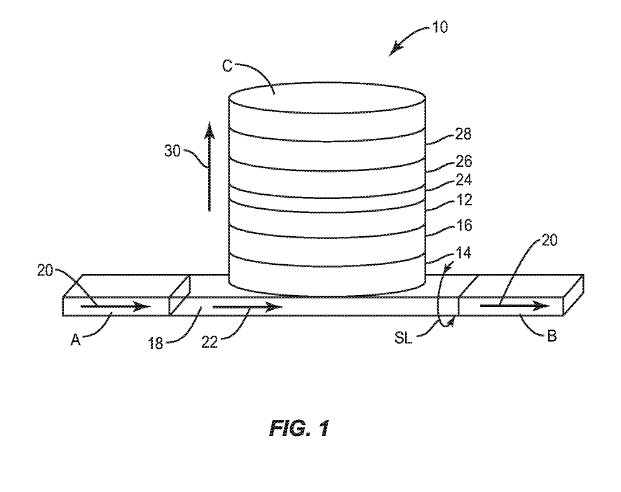

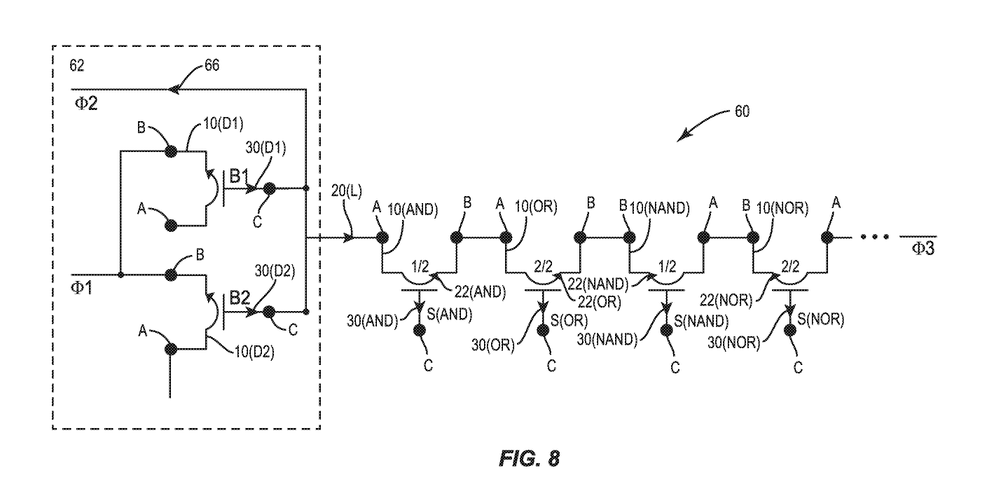

In this regard, before discussing exemplary spintronic logic gate arrangements below starting at FIG. 8, FIGS. 1-7 describe a GSHE MTJ element in order to explain how the GSHE MTJ element can be used in a spintronic logic gate. In this regard, FIG. 1 illustrates a cross-sectional view of one aspect of a GSHE MTJ element 10 that may be used in a spintronic logic gate. The cross-sectional view illustrates a stack of various layers, which may be utilized to provide the GSHE MTJ element 10. The GSHE MTJ element 10 shown in FIG. 1 includes a reference layer 12, a free layer 14, and a dielectric layer 16 that provides a tunnel barrier between the free layer 14 and the reference layer 12. The reference layer 12 has a magnetization that is fixed. In this aspect, the magnetization of the reference layer 12 is directed out of a page and is in-plane to the reference layer 12.

A GSHE electrode 18 is coupled to the free layer 14 and is formed from a GSHE material, such as β-Tantalum, β-Tungsten, Rubidium, and/or Platinum as non-limiting examples. The GSHE electrode 18 is configured to receive a charge current 20 and generate a GSHE spin current 22 in response to the charge current 20. More specifically, the GSHE electrode 18 is configured to produce a GSHE that converts the charge current 20 into the GSHE spin current 22. The charge current 20 may represent an input bit set of one or more bit states. For example, the charge current 20 may have a charge current magnitude set in accordance with the one or more bit states of the input bit set. As such, a spin current magnitude of the GSHE spin current 22 may be set in accordance with the charge current magnitude of the charge current 20. Since the charge current magnitude is set in accordance with the one or more bit states of the input bit set, the spin current magnitude may also be set in accordance with the one or more bit states of the input bit set. For instance, the GSHE MTJ element 10 is configured to store a bit state as a logical output bit state, and has a threshold current level that determines when the logical output bit state is switched from a logical value (e.g., a logical value of “0”) to an antipodal logical value (e.g., a logical value of “1”). Accordingly, the GSHE MTJ element 10 is configured to perform a logical operation on the input bit set by setting the logical output bit state based on whether the GSHE spin current 22 exceeds the threshold current level.

With regard to the free layer 14, a magnetization of the free layer 14 is transverse to a direction of propagation of the charge current 20 and in-plane to the free layer 14. A magnetic orientation alignment between the magnetization of the reference layer 12 and the magnetization of the free layer 14 represents the bit state (e.g., the logical output bit state) stored by the GSHE MTJ element 10. In this aspect, the magnetization of the free layer 14 may have a first magnetic orientation state where the magnetization of the free layer 14 is directed out of the page, and a second magnetic orientation state where the magnetization of the free layer 14 is directed into the page. As such, the bit state (e.g., the logical output bit state) stored by the GSHE MTJ element 10 is based on the magnetization of the free layer 14.

Since the magnetization of the reference layer 12 is fixed and the magnetization of the free layer 14 may be switched between the first magnetic orientation state and the second magnetic orientation state, the magnetic orientation alignment between the magnetization of the reference layer 12 and the magnetization of the free layer 14 may be provided in a parallel magnetic orientation alignment state and an anti-parallel magnetic orientation alignment state. More specifically, when the free layer 14 is in the first magnetic orientation state, the magnetic orientation alignment of the GSHE MTJ element 10 is provided in the parallel magnetic orientation alignment state because the magnetization of the free layer 14 and the magnetization of the reference layer 12 are aligned and in the same direction (i.e., the magnetization of the free layer 14 and the magnetization of the reference layer 12 both are directed out of the page). In this example, the bit state (e.g., the logical output bit state) stored by the GSHE MTJ element 10 represents a logical value of “0” when the magnetic orientation alignment of the GSHE MTJ element 10 is provided in the parallel magnetic orientation alignment state.

When the free layer 14 is in the anti-parallel magnetic orientation state, the magnetic orientation alignment of the GSHE MTJ element 10 is provided in the anti-parallel magnetic orientation alignment state because the magnetization of the free layer 14 and the magnetization of the reference layer 12 are not aligned, but in opposing directions (i.e., the magnetization of the free layer 14 is directed into the page and the magnetization of the reference layer 12 is directed out of the page). In this example, the bit state (e.g., the logical output bit state) stored by the GSHE MTJ element 10 represents a logical value of “1” when the magnetic orientation alignment of the GSHE MTJ element 10 is provided in the anti-parallel magnetic orientation alignment state. To set the magnetization of the free layer 14, the GSHE electrode 18 produces a GSHE that converts the charge current 20 into the GSHE spin current 22 due to spin-orbit interactions. The GSHE produced by the GSHE electrode 18 causes the GSHE spin current 22 to propagate substantially along an outer periphery of the GSHE electrode 18 and spin polarizes the GSHE spin current 22. More specifically, the GSHE spin current 22 is spin polarized such that a spin orientation of the GSHE spin current 22 is in-plane to an outer periphery of the GSHE electrode 18, but is traverse (e.g., orthogonal) to a direction of propagation of the charge current 20. The GSHE spin current 22 exerts a spin torque on the free layer 14 that can be utilized to change the magnetization of the free layer 14 between the first magnetic orientation state and the second magnetic orientation state. After the GSHE spin current 22 propagates out of the GSHE electrode 18, the spin polarization of the GSHE spin current 22 is lost and the GSHE spin current 22 is converted back into the charge current 20.

FIG. 1 illustrates that the GSHE MTJ element 10 has a charge current node A, a charge current node B, and a charge current node C. The GSHE MTJ element 10 may receive the charge current 20 so that the charge current 20 propagates from the charge current node A to the charge current node B, or the GSHE MTJ element 10 may receive the charge current 20 so that the charge current 20 propagates from the charge current node B to the charge current node A. In this manner, the GSHE MTJ element 10 can be switched from the second magnetic orientation state to the first magnetic orientation state and from the first magnetic orientation state to the second magnetic orientation state, as explained in further detail below. A resistance of the GSHE MTJ element 10 is provided between a charge current node C and the GSHE electrode 18. When the free layer 14 is in the second magnetic orientation state, the magnetic orientation alignment of the GSHE MTJ element 10 is in the anti-parallel magnetic orientation alignment state. Thus, the resistance of the GSHE MTJ element 10 between the charge current node C and the GSHE electrode 18 is provided in a first resistive state, which in this aspect is a high resistance state. When the free layer 14 is in the first magnetic orientation state, the magnetic orientation alignment of the GSHE MTJ element 10 is in the parallel magnetic orientation alignment state. Thus, the resistance of the GSHE MTJ element 10 between the charge current node C and the GSHE electrode 18 is provided in a second resistive state, which in this aspect is a low resistance state.

In FIG. 1, the charge current 20 is shown propagating from a charge current node A to a charge current node B. As a result, the GSHE spin current 22 generated in response to the charge current 20 is spin polarized along the outer periphery such that the spin orientation of the GSHE spin current 22 is aligned along a spin loop SL. In this case, if the magnetization of the free layer 14 is in the second magnetic orientation state and the GSHE spin current 22 is greater than the threshold current level, the magnetization of the free layer 14 is switched from the second magnetic orientation state to the first magnetic orientation state. However, if the magnetization of the free layer 14 is in the second magnetic orientation state but the GSHE spin current 22 is less than the threshold current level, the magnetization of the free layer 14 is maintained in the second magnetic orientation state. Finally, if the magnetization of the free layer 14 was already in the first magnetic orientation state, the magnetization of the free layer 14 is maintained in the first magnetic orientation state. When the free layer 14 is in the first magnetic orientation state, the magnetic orientation alignment of the GSHE MTJ element 10 is in the parallel magnetic orientation alignment state. Thus, the resistance of the GSHE MTJ element 10 between the charge current node C and the GSHE electrode 18 is provided in the first resistive state, which in this aspect is the low resistance state.

Similarly, the charge current 20 may be generated so as to propagate from the charge current node B to the charge current node A. As a result, the GSHE spin current 22 generated in response to the charge current 20 is spin polarized along the outer periphery such that the spin orientation of the GSHE spin current 22 is aligned opposite the spin loop SL shown in FIG. 1. In this case, if the magnetization of the free layer 14 is in the first magnetic orientation state and the charge current 20 is above the threshold current level, the magnetization of the free layer 14 is switched from the first magnetic orientation state to the second magnetic orientation state. However, if the magnetization of the free layer 14 is in the first magnetic orientation state but the GSHE spin current 22 is less than the threshold current level, the magnetization of the free layer 14 is maintained in the first magnetic orientation state. Finally, if the magnetization of the free layer 14 was already in the second magnetic orientation state, the magnetization of the free layer 14 is maintained in the second magnetic orientation state. When the free layer 14 is in the second magnetic orientation state, the magnetic orientation alignment of the GSHE MTJ element 10 is in the anti-parallel magnetic orientation alignment state. Thus, the resistance of the GSHE MTJ element 10 between the charge current node C and the GSHE electrode 18 is provided in the first resistive state, which in this aspect is the high resistance state.

In this aspect, the charge current node A is provided as a terminal by the GSHE MTJ element 10, the charge current node B is provided as another terminal by the GSHE MTJ element 10, and the charge current node C is provided as still another terminal by the GSHE MTJ element 10. As such, the charge current node A, the charge current node B, and the charge current node C may be formed from a metallic layer, such as copper (Cu). The GSHE electrode 18 is formed between the charge current node A and the charge current node B. However, the GSHE MTJ element 10 is formed such that the reference layer 12 and the free layer 14 are stacked between the GSHE electrode 18 and the charge current node C.

The GSHE MTJ element 10 further comprises a barrier layer 24, a pinning layer 26, and an antiferromagnetic layer 28. In this aspect, the charge current node C is provided on the antiferromagnetic layer 28 and the free layer 14 is provided on the GSHE electrode 18. The barrier layer 24, the pinning layer 26, and the antiferromagnetic layer 28 provide a magnetically rigid component so that the magnetic orientation of the reference layer 12 is fixed so as to be directed out of the page. The barrier layer 24 is formed on the reference layer 12, while the pinning layer 26 is formed on the barrier layer 24. In this manner, the barrier layer 24 is provided between the pinning layer 26 and the reference layer 12. The antiferromagnetic layer 28 helps secure the magnetization of the pinning layer 26.

To read the bit state (e.g., the logical output bit state) stored by the GSHE MTJ element 10, the GSHE MTJ element 10 is configured to generate a charge current 30 through the GSHE MTJ element 10 propagating from/to the GSHE electrode 18 to/from the charge current node C. When the magnetic orientation alignment of the GSHE MTJ element 10 is in the anti-parallel magnetic orientation alignment state and the resistance of the GSHE MTJ element 10 is provided in the first resistive state (i.e., the high resistance state), the charge current 30 is in a low current state. When the GSHE MTJ element 10 is in the parallel magnetic orientation alignment state and the resistance of the GSHE MTJ element 10 is provided in the second resistive state (i.e., the low resistance state), the charge current 30 is in a high current state. In this manner, the charge current 30 can be used to represent the bit state (e.g., a logical value of “1” or “0”) being stored by the GSHE MTJ element 10. The GSHE MTJ element 10 is inherently non-volatile, and thus may be used to store the corresponding bit state (e.g., the logical value of “1” or “0”) without requiring a separate sequential state element (e.g., a latch, flip-flop, etc.). The magnetic orientation alignment and the resistance (and thus the bit state) of the GSHE MTJ element 10 can be sensed by detecting the resistance, a voltage level, and/or a current magnitude of the charge current 30 between the GSHE electrode 18 and the charge current node C.

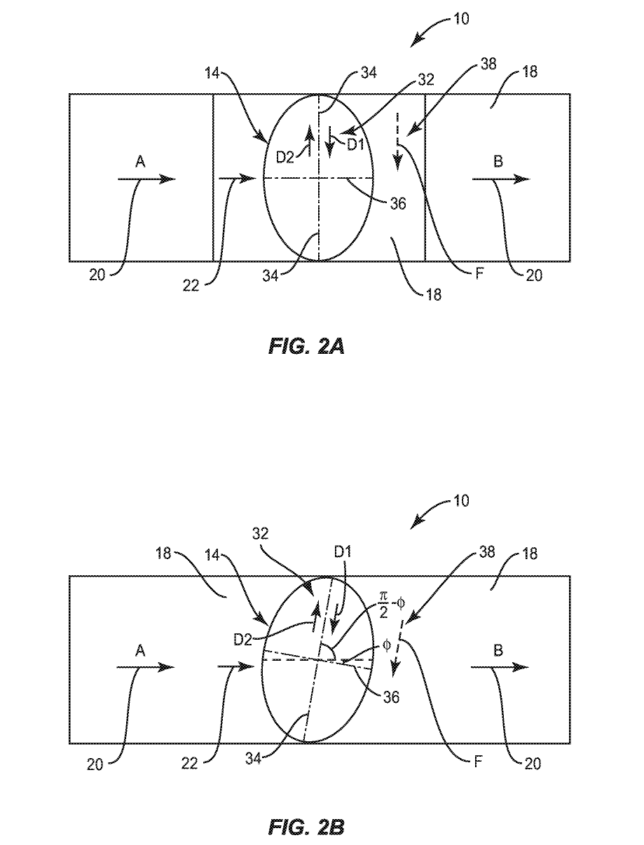

FIG. 2A illustrates a top-down view of one exemplary aspect of the GSHE electrode 18 and the free layer 14 of the GSHE MTJ element 10 shown in FIG. 1. More specifically, FIG. 2A shows a magnetization 32 of the free layer 14, where the free layer 14 is elliptical in shape. In this aspect, the magnetization 32 of the free layer 14 is aligned with a major axis 34 of the free layer 14, while the charge current 20 propagates so as to be aligned with a minor axis 36 of the free layer 14. In this aspect, the major axis 34 is an easy axis of magnetization for the free layer 14, while the minor axis 36 is a hard axis of magnetization for the free layer 14. When the charge current 20 is provided so as to propagate from the charge current node A to the charge current node B and is provided above the threshold current level, the magnetization 32 of the free layer 14 is switched to or is maintained in the first magnetic orientation state where the magnetization 32 is provided in a direction D1. In this aspect, the direction D1 is aligned with the major axis 34 and is parallel to a direction F of a magnetization 38 of the reference layer 12 (shown in FIG. 1). Thus, the magnetic orientation alignment between the magnetization 38 of the reference layer 12 and the magnetization 32 of the free layer 14 is in the parallel magnetic orientation alignment state because the magnetization 32 of the free layer 14 and the magnetization 38 of the reference layer 12 are parallel with respect to one another. Since the major axis 34 and the minor axis 36 are orthogonal to one another, the magnetization 32 of the free layer 14 and the magnetization 38 of the reference layer 12 are also orthogonal to the minor axis 36.

When the charge current 20 is provided so as to propagate in a direction from the charge current node B to the charge current node A and is provided above the threshold current level, the magnetization 32 of the free layer 14 is switched to or is maintained in the second magnetic orientation state where the magnetization 32 is provided in a direction D2. The direction D2 is parallel to the major axis 34 and is anti-parallel to the direction F of the magnetization 38 of the reference layer 12. Thus, the magnetic orientation alignment of the GSHE MTJ element 10 shown in FIG. 1 is in the anti-parallel magnetic orientation alignment state, because the magnetization 32 of the free layer 14 and the magnetization 38 of the reference layer 12 are anti-parallel with respect to one another. Since the major axis 34 and the minor axis 36 are orthogonal to one another, the magnetization 32 of the free layer 14 and the magnetization 38 of the reference layer 12 are also orthogonal to the minor axis 36. Note that since the charge current 20 propagates orthogonally with respect to the major axis 34 (i.e., the easy axis) and in alignment with the minor axis 36 (i.e., the hard axis), a switching field applied by the GSHE spin current 22 to the free layer 14 is along the major axis 34. Thus, the free layer 14 is positioned in the most favorable orientation of magnetic anisotropy. The GSHE MTJ element 10 shown in FIG. 2A is thus configured such that the threshold current level is at a maximum.

FIG. 2B illustrates a top-down view of another exemplary aspect of the GSHE electrode 18 and the free layer 14 of the GSHE MTJ element 10 shown in FIG. 1. As in the aspect shown in FIG. 2A, the magnetization 32 of the free layer 14 can be provided in the first magnetic orientation state with the direction D1, which is parallel to direction F of the magnetization 38 of the reference layer 12. The magnetization 32 of the free layer 14 can also be provided in the second magnetic orientation state with the direction D2, which is anti-parallel to the direction F of the magnetization 38 of reference layer 12. However, the charge current 20 shown in FIG. 2B propagates so as to be substantially aligned with an axis 39. In this aspect, the free layer 14 is positioned such that the minor axis 36 (i.e., the hard axis) of the free layer 14 is tilted at an angle φ with respect to the propagation of the charge current 20. As such, the minor axis 36 of the free layer 14 is tilted at the angle φ relative to the axis 39. Thus, the major axis 34 (i.e., the easy axis) is tilted at an angle

$$\frac{π}{2} - φ$$

with respect to the propagation of the charge current 20. Free of an external magnetic field, the magnetization 32 of the free layer 14 and the magnetization 38 of the reference layer 12 are aligned along the major axis 34 of the free layer 14. Therefore, the directions D1, D2, and F are also tilted at the angle

$$\frac{π}{2} - φ$$

with respect to the propagation of the charge current 20. Accordingly, the GSHE MTJ element 10 shown in FIG. 2B has the free layer 14 positioned such that the charge current 20 propagates with a directional component along the major axis 34 (i.e., the easy axis) and a directional component along the minor axis 36 (i.e., the hard axis). As such, the switching field applied by the GSHE spin current 22 to the free layer 14 has a directional component along the major axis 34 and a directional component along the minor axis 36.

The GSHE MTJ element 10 shown in FIG. 2B is thus configured such that the threshold current level is lower in comparison to the aspect shown in FIG. 2A. Setting the angle φ thus provides a technique for controlling the threshold current level of the GSHE MTJ element 10. The threshold current level of the GSHE MTJ element 10 is at a minimum when the angle φ is around

$$\pm \frac{π}{4}$$

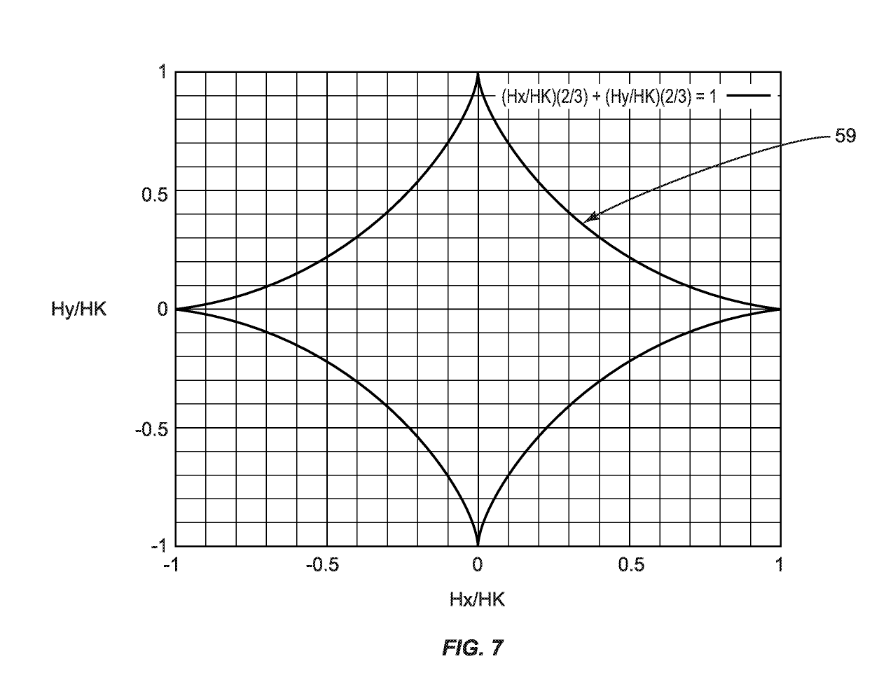

### (see FIG. 7).

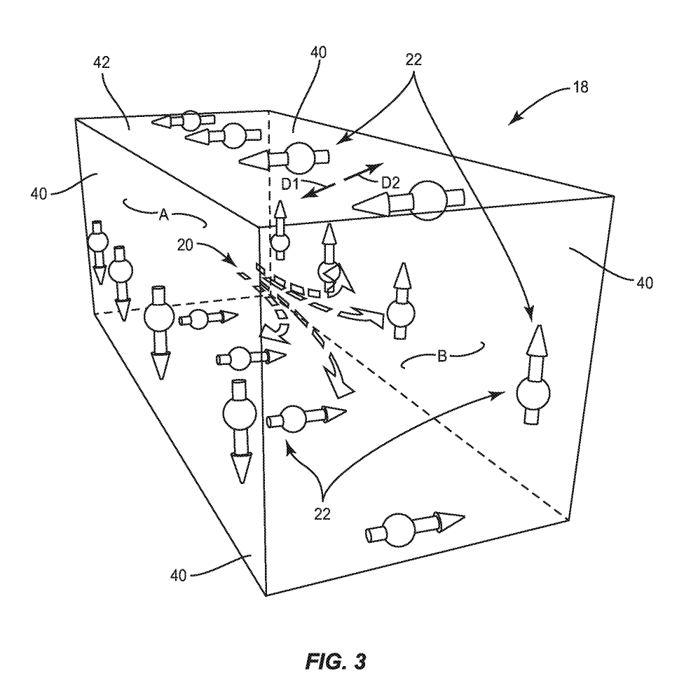

FIG. 3 is a perspective view of the GSHE electrode 18 of the GSHE MTJ element 10 shown in FIGS. 1, 2A, and 2B. The GSHE electrode 18 is configured to provide a GSHE that converts the charge current 20 to the GSHE spin current 22. The GSHE electrode 18 is formed from a GSHE material. The GSHE material results in the GSHE, causing a spin-polarized diffusion of electrons in directions that are traverse to the flow of the charge current 20, as shown in FIG. 3. The GSHE is due to spin-orbit coupling in the GSHE electrode 18, and the spin-polarized diffusion deflects the electrons to an outer periphery 40 of the GSHE electrode 18. As a result, the charge current 20 is converted into the GSHE spin current 22. The GSHE material that forms the GSHE electrode 18 may be a metal with a high atomic number, such as Tantalum, Rubidium, Tungsten, and/or Platinum. For example, the GSHE electrode 18 may be formed from high-resistivity forms of beta-Tantalum and beta-Tungsten. As shown in FIG. 3, the GSHE spin current 22 is spin-polarized such that a spin orientation of the GSHE spin current 22 is in-plane to the outer periphery 40 of the GSHE electrode 18, but traverse (e.g., orthogonal) to the direction of propagation of the charge current 20.

In this aspect, the charge current 20 in FIG. 3 is provided so as to propagate from the charge current node A to the charge current node B. Furthermore, the free layer 14 (shown in FIG. 1) has been formed on an electrode surface 42 at the outer periphery 40 of the GSHE electrode 18. As shown in FIG. 3, the GSHE spin current 22 thus has a spin polarization in the direction D1 along the electrode surface 42. Although electrons in the GSHE spin current 22 are reflected by the free layer 14, the GSHE spin current 22 exerts a spin torque on the free layer 14 that drives the magnetization of the free layer 14 in the direction D1. If the charge current 20 has been provided so as to propagate from the charge current node B to the charge current node A, the GSHE spin current 22 is generated so as to have the spin polarization in the direction D2 along the electrode surface 42. In this case, the GSHE spin current 22 exerts a spin torque on the free layer 14 that drives the magnetization 32 (shown in FIGS. 2A and 2B) of the free layer 14 in the direction D2. After the GSHE spin current 22 propagates out of the GSHE electrode 18, the spin polarization of the GSHE spin current 22 is lost and the GSHE spin current 22 is converted back into the charge current 20.

At the electrode surface 42 of the GSHE electrode 18 adjoining the free layer 14, the GSHE spin current 22 is generated by the GSHE electrode 18 where a current magnitude of the GSHE spin current 22 is related to a current magnitude of the charge current 20 in accordance to a Spin Hall angle θ_{SH} (not shown). The Spin Hall angle θ_{SH} defines a Spin Hall ratio:

θ_{SH}=(J_{S}/(/2))/(J_{C}/e)

J_{S}=a current density of the GSHE spin current 22
=Planck's constant divided by 2π
J_{C}=a current density of the charge current 20
e=charge of an electron

Forming the GSHE electrode 18 from Tantalum, Rubidium, Tungsten, and/or Platinum in high-resistivity forms may improve the GSHE in orders of magnitude to ˜0.30. As such, the GSHE provided by the GSHE electrode 18 is several orders of magnitude greater than a Spin Hall Effect (SHE) produced with previously known electrodes. The GSHE generated from the charge current 20 by the GSHE electrode 18 thus provides an efficient way to convert the charge current 20 into the charge current 30.

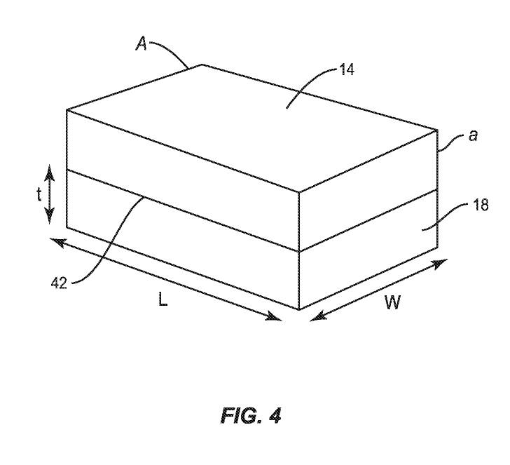

FIG. 4 illustrates one aspect of the free layer 14 and the GSHE electrode 18, wherein the electrode surface 42 of the GSHE electrode 18 adjoins the free layer 14. The ratio of a current magnitude I_{S} of the GSHE spin current 22 and a current magnitude I_{C} of the charge current 20 is related to a geometry of the free layer 14 and the GSHE electrode 18. In FIG. 4, a length of the free layer 14 and the GSHE electrode 18 is shown as L, a width of the free layer 14 and the GSHE electrode 18 is shown as W, and a height of the GSHE electrode 18 is shown as t. Thus, an area a that the charge current 20 passes through is defined as the height t multiplied times the width W. An area A that the spin current 22 passes through is defined as the length L multiplied by the width W. The ratio of the current magnitude I_{S} of the GSHE spin current 22 and the current magnitude l_{C} of the charge current 20 can therefore be shown as:

(I_{S}/(/2))/(I_{C}/e))=(J_{S}A)/(J_{C}a)=θ_{SH}(A/a)=θ_{SH}(L/t)

As such, for the Spin Hall angle θ_{SH} of ˜0.30, with a length L of approximately 50-100 nm and a height t of approximately 2 nm, the ratio (I_{S}/(/2))/(I_{C}/e) of the current magnitude I_{S} and the current magnitude I_{C} is between 7.5 and 15. Spin torque transfer (STT) provides an equivalent ratio of only ˜0.60. Accordingly, in comparison to spin torque transfer (STT), this represents hundreds of times less power being consumed by the GSHE MTJ element 10 when compared to STT techniques.

FIG. 5 is an operative symbol used to represent the GSHE MTJ element 10 of FIG. 1. The GSHE MTJ element 10 is configured to receive the charge current 20. The charge current 20 propagates in a current direction from the charge current node A to the charge current node B when received at the charge current node A. When the charge current 20 is received at the charge current node B, the charge current 20 propagates in a current direction from the charge current node B to the charge current node A. In response to the charge current 20, the GSHE MTJ element 10 generates the GSHE spin current 22 between the charge current node A and the charge current node B.

An integer n is an integer number of MTJ input nodes of other MTJ elements that are to be connected to the GSHE MTJ element 10. An integer m indicates how many of the other MTJ elements are provided having a resistance in the low resistance state so that the GSHE MTJ element 10 generates the GSHE spin current 22 at a level greater than or equal to the threshold current level. If a number of the other MTJ elements that have their resistances set in the low resistance state is equal to or greater than the integer number m, the GSHE spin current 22 switches the magnetic orientation alignment of the GSHE MTJ element 10 to the parallel magnetic orientation state when the charge current 20 propagates in a current direction from the charge current node A to the charge current node B. If the number of the other MTJ elements that have their resistances set in the low resistance state is equal to or greater than the integer number m, the GSHE spin current 22 switches the magnetic orientation alignment of the GSHE MTJ element 10 to the anti-parallel magnetic orientation state when the charge current 20 propagates in a current direction from the charge current node B to the charge current node A. Otherwise, if the number of the other MTJ elements that have their resistances set in the low resistance state is less than the integer number m, the magnetic orientation alignment of the GSHE MTJ element 10 is maintained. The GSHE MTJ element 10 may be designed and fabricated to have the integer number m at a particular integer value. Thus, the integer number m indicates the threshold current level of the GSHE MTJ element 10. To read the bit state (i.e., the logical output bit state) stored by the GSHE MTJ element 10, the GSHE MTJ element 10 is configured to generate the charge current 30 representing the bit state from the charge current node C. The GSHE MTJ element 10 may generate the charge current 30 in response to a control voltage applied between the charge current node C and either the charge current node A or the charge current node B.

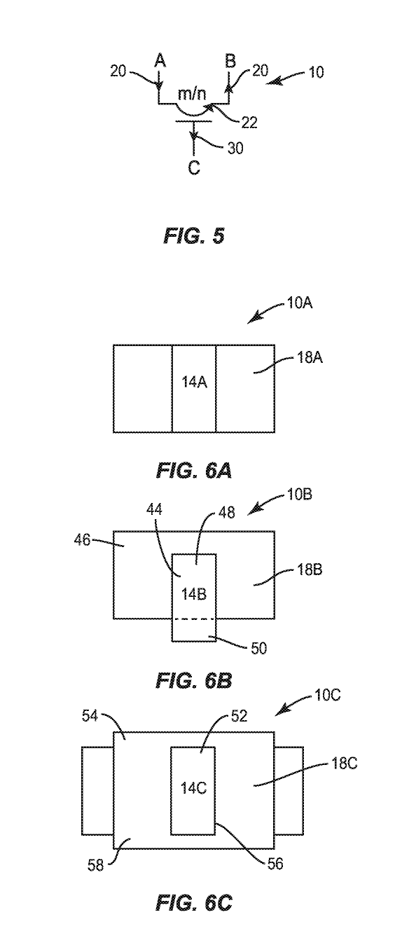

FIG. 6A illustrates an exemplary aspect of a GSHE MTJ element 10A, which is one aspect of the GSHE MTJ element 10 described above with regard to FIG. 1. A free layer 14A of the GSHE MTJ element 10A and a GSHE electrode 18A are shown in FIG. 6A, and are aspects of the free layer 14 and the GSHE electrode 18 shown in FIG. 1, respectively. To control the integer m (not shown), a thickness of the free layer 14A may be controlled. Accordingly, by controlling the thickness of the free layer 14A, the integer m, and thus the threshold current level, is set.

It may be difficult to precisely control the thickness of the free layer 14A to set the threshold current level. As such, FIG. 6B illustrates another aspect of a GSHE MTJ element 10B. A free layer 14B of the GSHE MTJ element 10B and a GSHE electrode 18B are shown in FIG. 6B, and are aspects of the free layer 14 and the GSHE electrode 18 shown in FIG. 1, respectively. The free layer 14B has a magnetic layer surface 44 disposed on an electrode surface 46 of the GSHE electrode 18B such that the magnetic layer surface 44 partially overlaps the electrode surface 46 of the GSHE electrode 18B. More specifically, the magnetic layer surface 44 is disposed on the electrode surface 46 such that a first area 48 of the magnetic layer surface 44 overlaps the electrode surface 46 of the GSHE electrode 18B, and a second area 50 of the magnetic layer surface 44 does not overlap the electrode surface 46 of the GSHE electrode 18B. In this manner, the integer m is set along with the threshold current level of the GSHE MTJ element 10B. Accordingly, controlling the amount of overlap between the free layer 14B and the GSHE electrode 18B can be used to set the threshold current level of the GSHE MTJ element 10B.

FIG. 6C illustrates another aspect of a GSHE MTJ element 10C. A free layer 14C of the GSHE MTJ element 10C and a GSHE electrode 18C are shown in FIG. 6C, and are aspects of the free layer 14 and the GSHE electrode 18 shown in FIG. 1, respectively. The free layer 14C has a magnetic layer surface 52 disposed on an electrode surface 54 of the GSHE electrode 18C. More specifically, the GSHE electrode 18C is shaped such that a first area 56 of the electrode surface 54 overlaps the magnetic layer surface 52. A second area 58 of the electrode surface 54 does not overlap the magnetic layer surface 52. The second area 58 of the electrode surface 54 surrounds the magnetic layer surface 52. In this manner, the integer m is set along with the threshold current level of the GSHE MTJ element 10C. As such, controlling a size of the first area 56 and a size of the second area 58 of the electrode surface 54 can be used to determine the threshold current level.

FIG. 7 is a graph that illustrates one aspect of a Stoner-Wohlfarth Switching Astroid 59 that indicates the threshold current level of the GSHE MTJ element 10 shown in FIG. 1. Assuming that an easy axis (e.g., the major axis 34 in FIGS. 2A and 2B) of the free layer 14 is an x-axis of the free layer 14, while a y-axis (e.g., the minor axis 36 in FIGS. 2A and 2B) is in-plane to the free layer 14 but orthogonal to the x-axis, a switching field H applied to the free layer 14 has a switching field component Hₓ along the x-axis and a switching field component H_{y} along a y-axis. In this case, the switching field H is generated as a result of the GSHE spin current 22. A magnetic anisotropy field (e.g., the magnetization 32 of the free layer 14 shown in FIGS. 2A and 2B) is represented by HK. The Stoner-Wohlfarth Switching Astroid 59 shown in FIG. 7 indicates a threshold field magnitude of the switching field component Hₓ and a threshold field magnitude of the switching field component H_{y} that switches the magnetization 32 of the free layer 14 from one magnetic orientation alignment state to another magnetic orientation alignment state (e.g., from the first magnetic orientation state to the second magnetic orientation state or from the second magnetic orientation state to the first magnetic orientation state). Consequently, in order to switch the magnetization 32 of the free layer 14, the GSHE spin current 22 (shown in FIG. 1) has to generate the switching field H such that the switching field component Hₓ exceeds its threshold field magnitude and the switching field component H_{y} exceeds its threshold field magnitude, which are plotted along the Stoner-Wohlfarth Switching Astroid 59. Accordingly, the Stoner-Wohlfarth Switching Astroid 59 indicates the threshold current level of the GSHE MTJ element 10. In this example, the Stoner-Wohlfarth Switching Astroid 59 has been normalized with respect to the magnetic anisotropy field HK.

The equation for the Stoner-Wohlfarth Switching Astroid 59 of FIG. 7 is

$$\frac{{H}_{x}}{{H}_{K}} \frac{2}{3} + \frac{{H}_{y}}{{H}_{K}} \frac{2}{3} = 1.$$

The Stoner-Wohlfarth Switching Astroid 59 of FIG. 7 demonstrates that the threshold field magnitude of the switching field component Hₓ and the threshold field magnitude of the switching field component H_{y} change as an angle between the magnetization 32 and the switching field H change. Thus, the threshold current level of the GSHE MTJ element 10 changes as the angle between the easy axis and the direction of propagation of the charge current 20 changes. Accordingly, the threshold current level is different with regard to the aspects of the GSHE MTJ element 10 shown in FIGS. 2A and 2B. As a result, the integer value of the GSHE MTJ element 10 may be set by the angle φ (see FIG. 2B).

FIG. 8 illustrates one aspect of a spintronic logic gate 60 which may be utilized to perform logical operations, such as an AND operation, an OR operation, a NOR operation, or a NAND operation. The spintronic logic gate 60 includes a charge current generation circuit 62 and GSHE MTJ elements 10(AND), 10(OR), 10(NAND), and 10(NOR), each of which is an aspect of the GSHE MTJ element 10 described above with respect to FIG. 1. Thus, each of the GSHE MTJ elements 10(AND), 10(OR), 10(NAND), and 10(NOR) includes one aspect of the charge current node A, the charge current node B, and the charge current node C. As explained in further detail below, the logical operation performed by each of the GSHE MTJ elements 10(AND), 10(OR), 10(NOR), and 10(NAND) is determined by appropriately connecting the charge current nodes A, B and by selecting appropriate integer values for the integers n, m. The integer n of each is equal to two (2). Each the GSHE MTJ elements 10(AND), 10(OR), 10(NAND), and 10(NOR) has a threshold current level, which is indicated by the integer m. The integer m of the GSHE MTJ element 10(AND) is equal to one (1), the integer m of the GSHE MTJ element 10(OR) is equal to two (2), the integer m of the GSHE MTJ element 10(NAND) is equal to one (1), and the integer m of the GSHE MTJ element 10(NOR) is equal to two (2). It should be noted that throughout the description of the figures, a logical value of “0” for a bit state is represented by the parallel magnetic orientation alignment state, the low resistive state, and the high current magnitude, while a logical value of “1” for the bit state is represented by the anti-parallel magnetic orientation alignment state, the high resistive state, and the low current magnitude.

The charge current generation circuit 62 is configured to generate a charge current 20(L) representing an input bit set. The input bit set may include one or more input bit states for the logical operations performed by each of the GSHE MTJ elements 10(AND), 10(OR), 10(NAND), and 10(NOR). In this aspect, the charge current generation circuit 62 may be further configured to store the input bit set. With regard to the charge current generation circuit 62 shown in FIG. 8, the charge current generation circuit 62 is configured to store two input bit states in the input bit set and to generate the charge current 20(L) such that the charge current 20(L) represents the two input bit states in the input bit set.

To store the input bit set and generate the charge current 20(L), the charge current generation circuit 62 may include a set of one or more MTJ elements. In this aspect, the charge current generation circuit 62 includes a GSHE MTJ element 10(D1) and a GSHE MTJ element 10(D2), each of which is an aspect of the GSHE MTJ element 10 described above with respect to FIG. 1. Thus, each of the GSHE MTJ elements 10(D1) and 10(D2) includes one aspect of the charge current node A, the charge current node B, and the charge current node C. The GSHE MTJ element 10(D1) is configured to store a first input bit state of the input bit set, while the GSHE MTJ element 10(D2) is configured to store a second input bit state of the input bit set. In one aspect, the first input bit state and the second input bit state may be set by charge currents (not shown) that represent the first input bit state and the second input bit state. For example, a write voltage representing the first input bit state may be applied between the charge current node A and the charge current node B of the GSHE MTJ element 10(D1). As such, a charge current (not shown) representing the first input bit state may be generated in response to the write voltage, thereby setting the first input bit state stored by the GSHE MTJ element 10(D1). Similarly, a write voltage representing the second input bit state may be applied between the charge current node A and the charge current node B of the GSHE MTJ element 10(D2). As such, a charge current (not shown) representing the second input bit state may be generated in response to the write voltage, thereby setting the second input bit state stored by the GSHE MTJ element 10(D2).

The GSHE MTJ element 10(D1) and the GSHE MTJ element 10(D2) in the charge current generation circuit 62 are operably associated such that the GSHE MTJ element 10(D1) and the GSHE MTJ element 10(D2) generate the charge current 20(L) that represents both the first input bit state and the second input bit state of the input bit set. In the aspect of the charge current generation circuit 62 shown in FIG. 8, the GSHE MTJ element 10(D1) and the GSHE MTJ element 10(D2) are coupled in parallel. To generate the charge current 20(L), the GSHE MTJ element 10(D1) is configured to generate a charge current 30(D1) that represents the first input bit state, and the GSHE MTJ element 10(D2) is configured to generate a charge current 30(D2) that represents the second input bit state. The charge current 30(D1) is generated from the charge current node C of the GSHE MTJ element 10(D1) and the charge current 30(D2) is generated from the charge current node C of the GSHE MTJ element 10(D2). The charge current node C of the GSHE MTJ element 10(D1) and the charge current node C of the GSHE MTJ element 10(D2) are connected to one another. As such, the charge current 30(D1) and the charge current 30(D2) combine to provide the charge current 20(L). The GSHE MTJ element 10(D1) and the GSHE MTJ element 10(D2) are thus coupled such that the charge current 20(L) includes the charge current 30(D1) and the charge current 30(D2). As such, the charge current 20(L) simultaneously represents the first input bit state and the second input bit state of the input bit set.

For example, assume that both the GSHE MTJ element 10(D1) and the GSHE MTJ element 10(D2) are in the parallel magnetic orientation alignment state, and thus the first input bit state and the second input bit state both have a logical value of “0.” If the charge current 30(D1) and the charge current 30(D2) both have the high current magnitude, a charge current magnitude of the charge current 20(L) will be provided in a high current state. The charge current 20(L) thus represents the logical values of “00.”

Alternatively, if the GSHE MTJ element 10(D1) is in the parallel magnetic orientation alignment state and the GSHE MTJ element 10(D2) is in the anti-parallel magnetic orientation alignment state, the first input bit state has a logical value of “0” and the second input bit state has a logical value of “1.” In this case, the charge current 30(D1) has the high current magnitude and the charge current 30(D2) has the low current magnitude. The charge current 30(D1) thus represents the first input bit state having a logical value of “0” and the charge current 30(D2) thus represents the second input bit state having a logical value of “1.” Additionally, if the GSHE MTJ element 10(D1) is in the anti-parallel magnetic orientation alignment state and the GSHE MTJ element 10(D2) is in the parallel magnetic orientation alignment state, the first input bit state has a logical value of “1” and the second input bit state has a logical value of “0.” The charge current 30(D1) thus represents the first input bit state having a logical value of “1.” Additionally, the charge current 30(D2) represents the second input bit state having a logical value of “0.” If one of the charge currents 30(D1), 30(D2) has the high current magnitude and the other of the charge currents 30(D1), 30(D2) has the low current magnitude, the charge current magnitude of the charge current 20(L) will be in a medium current state. The charge current 20(L) thus represents the logical value of “01” or the logical value of “10.”

Finally, assume that both the GSHE MTJ element 10(D1) and the GSHE MTJ element 10(D2) are in the anti-parallel magnetic orientation alignment state and thus the first input bit state and the second input bit state both have a logical value of “1.” If the charge current 30(D1) and the charge current 30(D2) both have the low current magnitude, the charge current magnitude of the charge current 20(L) will be provided in a low current state. The charge current 20(L) thus represents the logical value of “11.”

In this aspect, each of the GSHE MTJ elements 10(AND), 10(OR), 10(NAND), 10(NOR) is configured to set a logical output bit state for a logical operation and store the logical output bit state. The GSHE MTJ element 10(AND) performs an AND-based operation. More specifically, the GSHE MTJ element 10(AND) is configured to store and set a first logical output bit state for an AND operation. The GSHE MTJ element 10(AND) is configured to perform the AND operation through the arrangement of the charge current node A and the charge current node B of the GSHE MTJ element 10(AND) and through the selection of the integers m and n for the GSHE MTJ element 10(AND). The GSHE MTJ element 10(OR) performs an OR-based operation. More specifically, the GSHE MTJ element 10(OR) is configured to store and set a second logical output bit state for an OR operation. The GSHE MTJ element 10(OR) is configured to perform the OR operation through the arrangement of the charge current node A and the charge current node B of the GSHE MTJ element 10(OR) and through the selection of the integers m and n for the GSHE MTJ element 10(OR). The GSHE MTJ element 10(NAND) performs an AND-based operation. More specifically, the GSHE MTJ element 10(NAND) is configured to store and set a third logical output bit state for a NAND operation. The GSHE MTJ element 10(NAND) is configured to perform the NAND operation through the arrangement of the charge current node A and the charge current node B of the GSHE MTJ element 10(NAND) and through the selection of the integers m and n for the GSHE MTJ element 10(NAND). Finally, the GSHE MTJ element 10(NOR) is configured to store and set a fourth logical output bit state for a NOR operation. The GSHE MTJ element 10(NOR) performs an OR-based operation. More specifically, the GSHE MTJ element 10(NOR) is configured to perform the NOR operation through the arrangement of the charge current node A and the charge current node B of the GSHE MTJ element 10(NOR) and through the selection of the integers m and n for the GSHE MTJ element 10(NOR).

The GSHE MTJ elements 10(AND), 10(OR), 10(NAND), 10(NOR) shown in FIG. 8 are each coupled in series. Thus, each of the GSHE MTJ elements 10(AND), 10(OR), 10(NAND), 10(NOR) is configured to receive the charge current 20(L), which represents the input bit set as described above. The integer n of each of the GSHE MTJ elements 10(AND), 10(OR), 10(NAND), 10(NOR) is two (2), since the charge current generation circuit 62 has two MTJ input nodes provided by the GSHE MTJ element 10(D1) and the GSHE MTJ element 10(D2). As such, the input bit set from the charge current generation circuit 62 has two input bit states: the first input bit state stored by the GSHE MTJ element 10(D1) and the second input bit state stored by the GSHE MTJ element 10(D2). To describe the logical operations performed by the GSHE MTJ elements 10(AND), 10(OR), 10(NAND), 10(NOR), assume that the first logical output bit state stored by the GSHE MTJ element 10(AND) has been preset to have a logical value of “1” (i.e., the anti-parallel magnetic orientation alignment), the second logical output bit state stored by the GSHE MTJ element 10(OR) has been preset to have a logical value of “1” (i.e., the anti-parallel magnetic orientation alignment), the third logical output bit state stored by the GSHE MTJ element 10(NAND) has been preset to have a logical value of “0” (i.e., the parallel magnetic orientation alignment), and the fourth logical output bit state stored by the GSHE MTJ element 10(NOR) has been preset to have a logical value of “0” (i.e., the parallel magnetic orientation alignment). Since the GSHE MTJ elements 10(AND), 10(OR), 10(NAND), 10(NOR) are connected in series, an assumed preset can be accomplished by transmitting a charge current from the charge current node A of the GSHE MTJ element 10(NOR) to the charge current node A of the GSHE MTJ element 10(NAND).

As shown in FIG. 8, the charge current 20(L) is received by the GSHE MTJ element 10(AND) at the charge current node A of the GSHE MTJ element 10(AND). The GSHE MTJ element 10(AND) is configured to generate a GSHE spin current 22(AND) in response to the charge current 20(L). More specifically, the GSHE MTJ element 10(AND) is configured to produce a GSHE that converts the charge current 20(L) into the GSHE spin current 22(AND). The GSHE MTJ element 10(AND) has a threshold current level indicated by the integer m of the GSHE MTJ element 10(AND), which has an integer value of one (1), and the integer n of the GSHE MTJ element 10(AND), which has an integer value of two (2).

The GSHE MTJ element 10(AND) is configured to perform the AND operation on the input bit set (i.e., a first input bit state B1 and a second input bit state B2) by setting a first logical output bit state S(AND) based on whether the GSHE spin current 22(AND) exceeds the threshold current level of the GSHE MTJ element 10(AND). More specifically, the GSHE spin current 22(AND) exceeds the threshold current level of the GSHE MTJ element 10(AND) when either or both of the first input bit state B1 and second input bit state B2 have a logical value of “0.” When the GSHE spin current 22(AND) exceeds the threshold current level of the GSHE MTJ element 10(AND), the GSHE MTJ element 10(AND) is configured to switch the first logical output bit state S(AND) from the logical value of “1” (i.e., the anti-parallel magnetic orientation state) to the logical value of “0” (i.e., the parallel magnetic orientation state) because the charge current 20(L) is received at the charge current node A. Otherwise, the GSHE spin current 22(AND) is below the threshold current level of the GSHE MTJ element 10(AND) when both the first input bit state B1 and the second input bit state B2 have the logical value of “1.” When the GSHE spin current 22(AND) is below the threshold current level of the GSHE MTJ element 10(AND), the GSHE MTJ element 10(AND) is configured to maintain the first logical output bit state S(AND) at the logical value of “1” (i.e., the anti-parallel magnetic orientation state). At the charge current node B of the GSHE MTJ element 10(AND), the GSHE spin current 22(AND) is converted back into the charge current 20(L). To read the first logical output bit state S(AND), the GSHE MTJ element 10(AND) is configured to generate a charge current 30(AND) that represents the first logical output bit state S(AND) from the charge current node C of the GSHE MTJ element 10(AND).

The charge current 20(L) is received by the GSHE MTJ element 10(OR) at the charge current node A of the GSHE MTJ element 10(OR). The GSHE MTJ element 10(OR) is configured to generate a GSHE spin current 22(OR) in response to the charge current 20(L). More specifically, the GSHE MTJ element 10(OR) is configured to produce a GSHE that converts the charge current 20(L) into the GSHE spin current 22(OR). The GSHE MTJ element 10(OR) has a threshold current level indicated by the integer m of the GSHE MTJ element 10(OR), which has an integer value of two (2), and the integer n of the GSHE MTJ element 10(OR), which has an integer value of two (2).

The GSHE MTJ element 10(OR) is configured to perform the OR operation on the input bit set (i.e., the first input bit state B1 and the second input bit state B2) by setting a second logical output bit state S(OR) based on whether the GSHE spin current 22(OR) exceeds the threshold current level of the GSHE MTJ element 10(OR). More specifically, the GSHE spin current 22(OR) exceeds the threshold current level of the GSHE MTJ element 10(OR) when both the first input bit state B1 and second input bit state B2 have a logical value of “0.” When the GSHE spin current 22(OR) exceeds the threshold current level of the GSHE MTJ element 10(OR), the GSHE MTJ element 10(OR) is configured to switch the second logical output bit state S(OR) from the logical value of “1” (i.e., the anti-parallel magnetic orientation state) to the logical value of “0” (i.e., the parallel magnetic orientation state) because the charge current 20(L) is received at the charge current node A. Otherwise, the GSHE spin current 22(OR) is below the threshold current level of the GSHE MTJ element 10(OR) when either or both of the first input bit state B1 and the second input bit state B2 have the logical value of “1.” When the GSHE spin current 22(OR) is below the threshold current level of the GSHE MTJ element 10(OR), the GSHE MTJ element 10(OR) is configured to maintain the second logical output bit state S(OR) at the logical value of “1” (i.e., the anti-parallel magnetic orientation state). At the charge current node B of the GSHE MTJ element 10(OR), the GSHE spin current 22(OR) is converted back into the charge current 20(L). To read the second logical output bit state S(OR), the GSHE MTJ element 10(OR) is configured to generate a charge current 30(OR) that represents the second logical output bit state S(OR) from the charge current node C of the GSHE MTJ element 10(OR).

Next, the charge current 20(L) is received by the GSHE MTJ element 10(NAND) at the charge current node B of the GSHE MTJ element 10(NAND). The GSHE MTJ element 10(NAND) is configured to generate a GSHE spin current 22(NAND) in response to the charge current 20(L). More specifically, the GSHE MTJ element 10(NAND) is configured to produce a GSHE that converts the charge current 20(L) into the GSHE spin current 22(NAND). The GSHE MTJ element 10(NAND) has a threshold current level indicated by the integer m of the GSHE MTJ element 10, which has an integer value of one (1), and the integer n of the GSHE MTJ element 10(NAND), which has an integer value of two (2).

The GSHE MTJ element 10(NAND) is configured to perform the NAND operation on the input bit set (i.e., the first input bit state B1 and the second input bit state B2) by setting a third logical output bit state S(NAND) based on whether the GSHE spin current 22(NAND) exceeds the threshold current level of the GSHE MTJ element 10(NAND). More specifically, the GSHE spin current 22(NAND) exceeds the threshold current level of the GSHE MTJ element 10(NAND) when either or both of the first input bit state B1 and second input bit state B2 have a logical value of “0.” When the GSHE spin current 22(NAND) exceeds the threshold current level of the GSHE MTJ element 10(NAND), the GSHE MTJ element 10(NAND) is configured to switch the third logical output bit state S(NAND) from the logical value of “0” (i.e., the parallel magnetic orientation state) to the logical value of “1” (i.e., the anti-parallel magnetic orientation state) because the charge current 20(L) is received at the charge current node B. Otherwise, the GSHE spin current 22(NAND) is below the threshold current level of the GSHE MTJ element 10(NAND) when both the first input bit state B1 and the second input bit state B2 have the logical value of “1.” When the GSHE spin current 22(NAND) is below the threshold current level of the GSHE MTJ element 10(NAND), the GSHE MTJ element 10(NAND) is configured to maintain the third logical output bit state S(NAND) at the logical value of “0” (i.e., the parallel magnetic orientation state). At the charge current node A of the GSHE MTJ element 10(NAND), the GSHE spin current 22(NAND) is converted back into the charge current 20(L). To read the third logical output bit state S(NAND), the GSHE MTJ element 10(NAND) is configured to generate a charge current 30(NAND) that represents the third logical output bit state S(NAND) from the charge current node C of the GSHE MTJ element 10(NAND).

Finally, the charge current 20(L) is received by the GSHE MTJ element 10(NOR) at the charge current node B of the GSHE MTJ element 10(NOR). The GSHE MTJ element 10(NOR) is configured to generate a GSHE spin current 22(NOR) in response to the charge current 20(L). More specifically, the GSHE MTJ element 10(NOR) is configured to produce a GSHE that converts the charge current 20(L) into the GSHE spin current 22(NOR). The GSHE MTJ element 10(NOR) has a threshold current level indicated by the integer m of the GSHE MTJ element 10(NOR), which has an integer value of two (2), and the integer n of the GSHE MTJ element 10(NOR), which has an integer value of two (2).

The GSHE MTJ element 10(NOR) is configured to perform the NOR operation on the input bit set (i.e., the first input bit state B1 and the second input bit state B2) by setting a fourth logical output bit state S(NOR) based on whether the GSHE spin current 22(NOR) exceeds the threshold current level of the GSHE MTJ element 10(NOR). More specifically, the GSHE spin current 22(NOR) exceeds the threshold current level of the GSHE MTJ element 10(NOR) when both the first input bit state B1 and second input bit state B2 have a logical value of “0.” When the GSHE spin current 22(NOR) exceeds the threshold current level of the GSHE MTJ element 10(NOR), the GSHE MTJ element 10(NOR) is configured to switch the fourth logical output bit state S(NOR) from the logical value of “0” (i.e., the parallel magnetic orientation state) to the logical value of “1” (i.e., the anti-parallel magnetic orientation state) because the charge current 20(L) is received at the charge current node B. Otherwise, the GSHE spin current 22(NOR) is below the threshold current level of the GSHE MTJ element 10(NOR) when either the first input bit state B1 or the second input bit state B2 has the logical value of “1.” When the GSHE spin current 22(NOR) is below the threshold current level of the GSHE MTJ element 10(NOR), the GSHE MTJ element 10(NOR) is configured to maintain the fourth logical output bit state S(NOR) at the logical value of “0” (i.e., the parallel magnetic orientation state). At the charge current node A of the GSHE MTJ element 10(NOR), the GSHE spin current 22(NOR) is converted back into the charge current 20(L). To read the fourth logical output bit state S(NAND), the GSHE MTJ element 10(NOR) is configured to generate a charge current 30(NAND) that represents the fourth logical output bit state S(NOR) from the charge current node C of the GSHE MTJ element 10(NOR).

As explained in further detail below, the spintronic logic gate 60 is configured to receive a control signal Φ1, a control signal Φ2, and a control signal Φ3 in order to synchronize the operations of the GSHE MTJ elements 10(D1), 10(D2), 10(AND), 10(OR), 10(NAND), 10(NOR). In this manner, the bit states B1, B2, S(AND), S(OR), S(NOR), S(NAND) are updated in a synchronized manner. Note that the magnetic orientation alignments and resistances of the GSHE MTJ elements 10(AND), 10(OR), 10(NAND), and 10(NOR) can be used to store results of their respective logical operations without requiring separate sequential logic elements.

By providing the GSHE MTJ elements 10(D1), 10(D2) of the charge current generation circuit 62 in parallel, drive voltages to the GSHE MTJ elements 10(D1), 10(D2) do not have to be so high. However, when the GSHE MTJ elements 10(D1), 10(D2) are connected in parallel, the charge current generation circuit 62 may have reduced fanout performance since an input resistance of the charge current generation circuit 62 is reduced. Also, in this aspect, the GSHE MTJ elements 10(AND), 10(OR), 10(NAND), and 10(NOR) are coupled in series. The series arrangement provides for better fanout since the charge current 20 does not have to be increased due to the series arrangement when a number of the GSHE MTJ elements 10(AND), 10(OR), 10(NAND), and 10(NOR) that perform logical operations increases. However, the series arrangement also may require that higher drive voltages be provided to the GSHE MTJ elements 10(AND), 10(OR), 10(NAND), and 10(NOR).

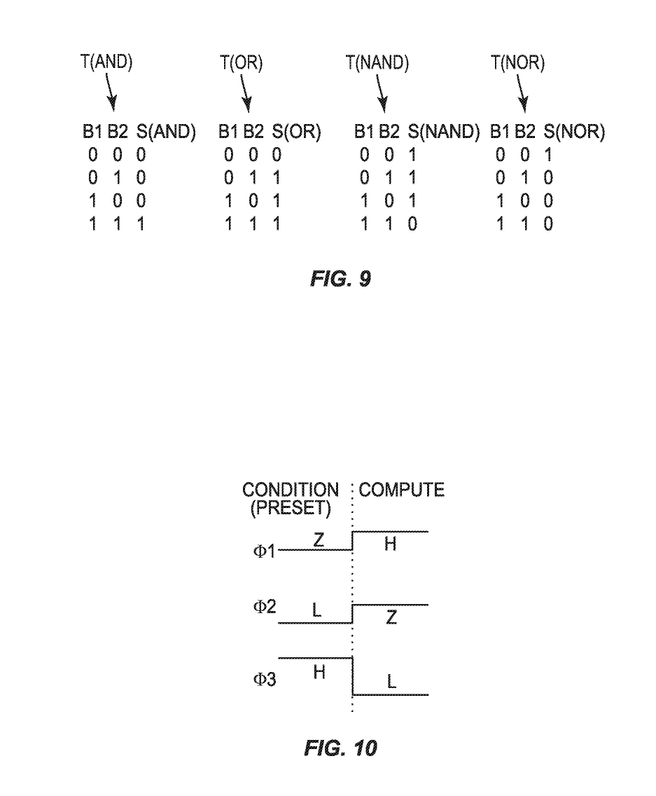

Referring now to FIGS. 8 and 9, FIG. 9 illustrates a group of truth tables T(AND), T(OR), T(NAND), and T(NOR) that collectively represent the logical operations performed by the GSHE MTJ elements 10(AND), 10(OR), 10(NAND), and 10(NOR) in the spintronic logic gate 60 shown in FIG. 8. The logical operations of the truth tables T(AND), T(OR), T(NAND), AND T(NOR) assume that the GSHE MTJ element 10(AND) has been preset to have a logical value of “1,” the GSHE MTJ element 10(OR) has been preset to have a logical value of “1,” the GSHE MTJ element 10(NAND) has been preset to have a logical value of “0,” and the GSHE MTJ element 10(NOR) has been preset to have a logical value of “0.”

Referring now to FIGS. 8 and 10, FIG. 10 illustrates a timing diagram representing a control state of the control signal Φ1, a control state of the control signal Φ2, and a control state of the control signal Φ3. A control state of H represents a high voltage state, a control state of L represents a low voltage state, and a control state of Z represents a high impedance state. During a preset mode, the control signal Φ1 is in the control state Z, the control signal Φ2 is in the control state L, and the control signal Φ3 is in the control state H. As such, a preset charge current 66 (shown in FIG. 8) is generated, propagating from the control signal Φ3 to the control signal Φ2. Note that the charge current 20(L) propagates in a first current direction across the GSHE MTJ elements 10(AND), 10(OR), 10(NAND), and 10(NOR), while the preset charge current 66 propagates in a second current direction across the GSHE MTJ elements 10(AND), 10(OR), 10(NAND), and 10(NOR), wherein the second current direction is antipodal to the first current direction. In this manner, the logical output bit states S(AND), S(OR), S(NAND), and S(NOR) of the GSHE MTJ elements 10(AND), 10(OR), 10(NAND), and 10(NOR) are preset to have logical values of “1,” “1,” “0,” and “0,” respectively. These are the default logical values of the logical output bit states S(AND), S(OR), S(NAND), and S(NOR). The first input bit state B1 and the second input bit state B2 of the GSHE MTJ elements 10(D1), 10(D2) may be set prior to the preset mode by write voltages. In alternative aspects, the first input bit state B1 and the second input bit state B2 may be set during the preset mode.

During a compute mode, the control signal Ω1 is in the control state H, the control signal Φ2 is in the control state Z, and the control signal Φ3 is in the control state L. As such, the charge current 20(L) is generated in order to read the first input bit state B1 and the second input bit state B2 stored by the charge current generation circuit 62, and to perform the logical operations of the GSHE MTJ elements 10(AND), 10(OR), 10(NAND), and 10(NOR) described above with respect to FIG. 8.

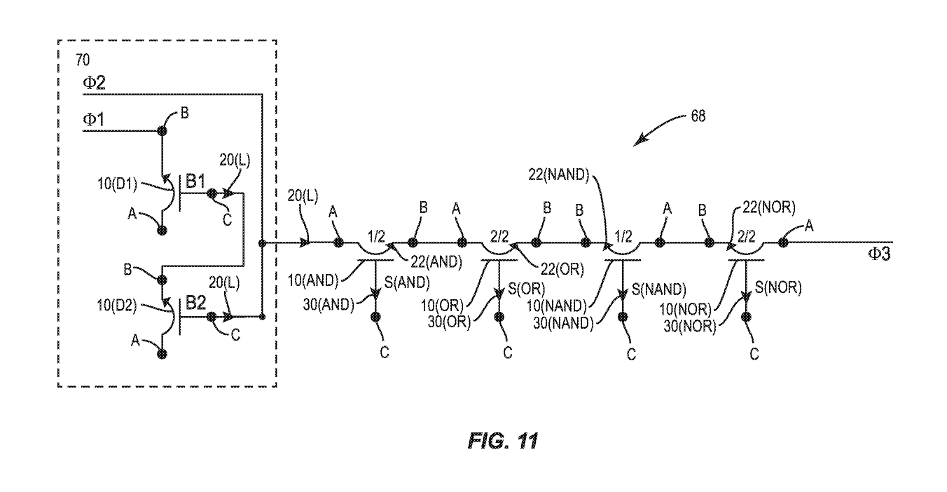

FIG. 11 illustrates another aspect of a spintronic logic gate 68. The spintronic logic gate 68 includes a charge current generation circuit 70 and the GSHE MTJ elements 10(AND), 10(OR), 10(NAND), and 10(NOR) described above with respect to FIG. 8. The GSHE MTJ elements 10(AND), 10(OR), 10(NAND), and 10(NOR) are also coupled in series in the same manner described above with respect to FIG. 8. Like the charge current generation circuit 62 illustrated in FIG. 8, the charge current generation circuit 70 includes the GSHE MTJ elements 10(D1), 10(D2) and is configured to generate the charge current 20(L) representing first input bit state B1 and the second input bit state B2. More specifically, the GSHE MTJ elements 10(D1) and the 10(D2) are operably associated so as to generate the charge current 20(L). However, the GSHE MTJ elements 10(D1), 10(D2) shown in FIG. 11 are coupled in series. Accordingly, the charge current node C of the GSHE MTJ element 10(D1) is connected to the charge current node B of the GSHE MTJ element 10(D2). Thus, the GSHE MTJ element 10(D1) and the GSHE MTJ element 10(D2) are coupled so that the charge current 20(L) propagates from the GSHE MTJ element 10(D1) and the GSHE MTJ element 10(D2). In this aspect, the charge current 20(L) propagates from the charge current node C of the GSHE MTJ element 10(D1) to the charge current node B of the GSHE MTJ element 10(D2). The charge current 20(L) then propagates from the charge current node C of the GSHE MTJ element 10(D2) to the GSHE MTJ elements 10(AND), 10(OR), 10(NAND), and 10(NOR). In comparison to the charge current generation circuit 62 of FIG. 8, the charge current generation circuit 70 may have a better fanout since connecting the GSHE MTJ elements 10(D1), 10(D2) in series increases the input resistance of the charge current generation circuit 70.

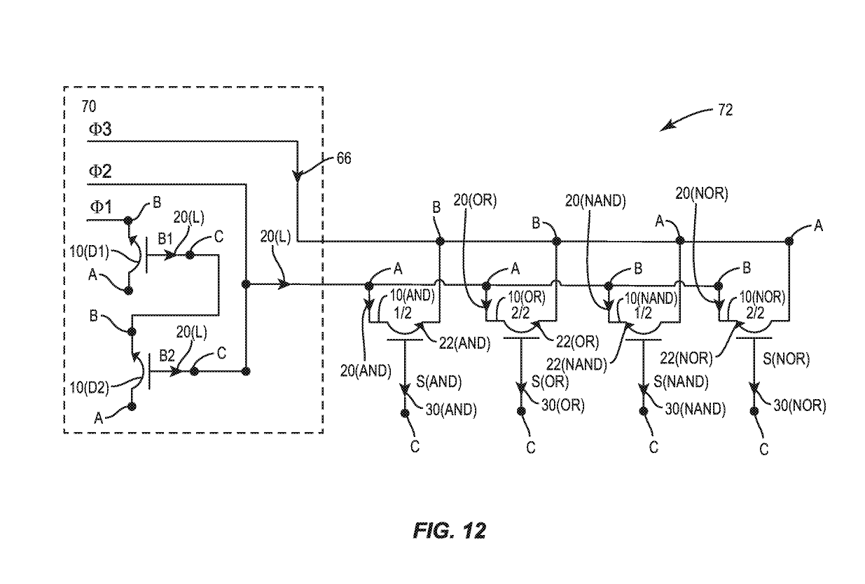

FIG. 12 illustrates another aspect of a spintronic logic gate 72. The spintronic logic gate 72 includes the charge current generation circuit 70 described above with respect to FIG. 11 and the GSHE MTJ elements 10(AND), 10(OR), 10(NAND), and 10(NOR) described above with respect to FIG. 8. Each of the GSHE MTJ elements 10(AND), 10(OR), 10(NAND), and 10(NOR) is configured to generate the GSHE spin currents 22(AND), 22(OR), 22(NAND), and 22(NOR), respectively, in response to the charge current 20(L). However, in this aspect, the GSHE MTJ elements 10(AND), 10(OR), 10(NAND), and 10(NOR) are coupled in parallel.

As such, in FIG. 12, the GSHE MTJ element 10(AND) is configured to receive a charge current 20(AND) at the charge current node A. The charge current 20(AND) is a portion of the charge current 20(L). Since the charge current 20(AND) is proportional to the charge current 20(L), the charge current 20(AND) also represents the first input bit state B1 and the second input bit state B2. The GSHE MTJ element 10(AND) is configured to produce the GSHE that converts the charge current 20(AND) to the GSHE spin current 22(AND). As described above, the GSHE MTJ element 10(AND) is configured to perform the AND operation based on whether the GSHE spin current 22(AND) exceeds the threshold current level of the GSHE MTJ element 10(AND).

Additionally, the GSHE MTJ element 10(OR) is configured to receive a charge current 20(OR) at the charge current node A. The charge current 20(OR) is a portion of the charge current 20(L). Since the charge current 20(OR) is proportional to the charge current 20(L), the charge current 20(OR) also represents the first input bit state B1 and the second input bit state B2. The GSHE MTJ element 10(OR) is configured to produce the GSHE that converts the charge current 20(OR) to the GSHE spin current 22(OR). As described above, the GSHE MTJ element 10(OR) is configured to perform the OR operation based on whether the GSHE spin current 22(OR) exceeds the threshold current level of the GSHE MTJ element 10(OR).

Furthermore, the GSHE MTJ element 10(NAND) is configured to receive a charge current 20(NAND) at the charge current node B. The charge current 20(NAND) is a portion of the charge current 20(L). Since the charge current 20(NAND) is proportional to the charge current 20(L), the charge current 20(NAND) also represents the first input bit state B1 and the second input bit state B2. The GSHE MTJ element 10(NAND) is configured to produce the GSHE that converts the charge current 20(NAND) to the GSHE spin current 22(NAND). As described above, the GSHE MTJ element 10(NAND) is configured to perform the NOR operation based on whether the GSHE spin current 22(NAND) exceeds the threshold current level of the GSHE MTJ element 10(NAND).

Finally, the GSHE MTJ element 10(NOR) is configured to receive a charge current 20(NOR) at the charge current node B. The charge current 20(NOR) is a portion of the charge current 20(L). Since the charge current 20(NOR) is proportional to the charge current 20(L), the charge current 20(NOR) also represents the first input bit state B1 and the second input bit state B2. The GSHE MTJ element 10(NOR) is configured to produce the GSHE that converts the charge current 20(NOR) to the GSHE spin current 22(NOR). As described above, the GSHE MTJ element 10(NOR) is configured to perform the NAND operation based on whether the GSHE spin current 22(NOR) exceeds the threshold current level of the GSHE MTJ element 10(NOR). By being coupled in parallel, the GSHE MTJ elements 10(AND), 10(OR), 10(NAND), and 10(NOR) may receive lower drive voltages but may have reduced fanout performance due to a high current demand with regard to the charge current 20(L).

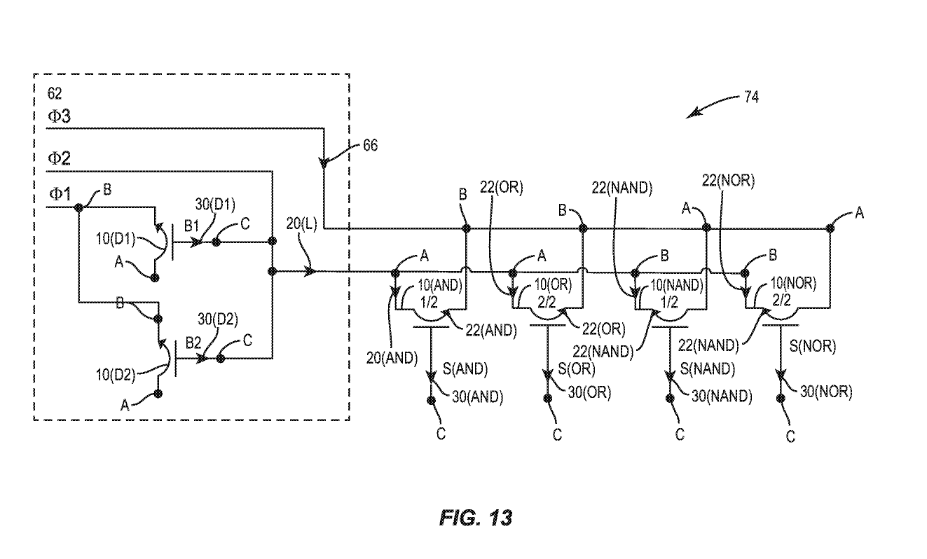

FIG. 13 illustrates another aspect of a spintronic logic gate 74. The spintronic logic gate 74 includes the charge current generation circuit 62 described above with respect to FIG. 8 and the GSHE MTJ elements 10(AND), 10(OR), 10(NAND), and 10(NOR). In this aspect, the GSHE MTJ elements 10(AND), 10(OR), 10(NAND), and 10(NOR) are coupled in parallel as described above in FIG. 12. As such, in comparison to the spintronic logic gate 60 shown in FIG. 8, the spintronic logic gate 68 shown in FIG. 11, and the spintronic logic gate 72 shown in FIG. 12, drive voltages to the spintronic logic gate 74 shown in FIG. 13 may be at their lowest. However, the spintronic logic gate 74 may have the worst fanout performance.

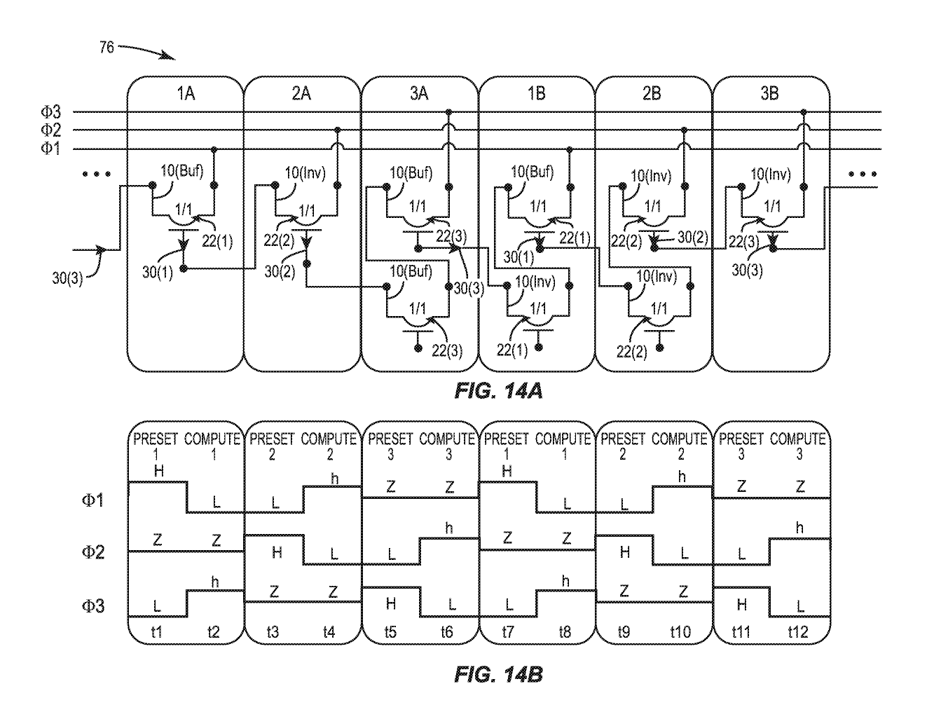

Referring now to FIGS. 14A and 14B, FIG. 14A illustrates one aspect of a pipeline circuit 76. The pipeline circuit 76 includes pipeline stages 1A and 1B (referred to generically as pipeline stages 1), pipeline stages 2A and 2B (referred to generically as pipeline stages 2), and pipeline stages 3A and 3B (referred to generically as pipeline stages 3). The pipeline stages 1, 2, and 3 are each configured to receive the control signal Φ1, the control signal Φ2, and the control signal Φ3 in order to synchronize the preset modes and the compute modes of each of the pipeline stages 1, 2, 3. GSHE MTJ elements 10(Buf) in FIG. 14A comprise aspects of the GSHE MTJ element 10 shown in FIG. 1, but are configured to perform a buffering operation by the depicted connection of the charge current nodes A, B and the selection of the integers m, n of each of the GSHE MTJ elements 10(Buf). GSHE MTJ elements 10(Inv) in FIG. 14A comprise aspects of the GSHE MTJ element 10 shown in FIG. 1, but are configured to perform an inversion operation by the depicted connection of the charge current nodes A, B and the selection of the integers m, n of each of the GSHE MTJ elements 10(Inv). In this regard, the integer n (see FIG. 5) of each of the GSHE MTJ elements 10(Buf) and the GSHE MTJ elements 10(Inv) is one (1). The integer m of each of the GSHE MTJ elements 10(Buf) and the MTJ elements 10(Inv) is also one (1).

As shown in FIGS. 14A and 14B, FIG. 14B illustrates a timing diagram that represents the control state of the control signal Φ1, the control state of the control signal Φ2, and the control state of the control signal Φ3. The control state H represents the high voltage state and the control state L represents the low voltage state. A voltage difference between the control state H and the control state L is set to produce charge current of sufficient current magnitude to preset any of the GSHE MTJ elements 10(Inv) and the GSHE MTJ elements 10(Buf) in the pipeline stages 1, 2, and 3 regardless of an integer value of the integer m provided by the GSHE MTJ elements 10(Inv) and the GSHE MTJ elements 10(Buf). The control state Z represents the high impedance state, while a control state h represents an intermediate high voltage state that is lower than the control state H but not sufficient to generate a current with a high enough current magnitude to switch the GSHE MTJ elements 10(Inv) and the GSHE MTJ elements 10(Buf) in the pipeline stages 1, 2, and 3. A voltage difference between the control state h and the control state L is set such that it generates a charge current of appropriate magnitude to allow the GSHE MTJ elements 10(Inv) and the GSHE MTJ elements 10(Buf) to perform their respective logic functions while not impacting bit states being stored by the GSHE MTJ elements 10(Inv) and the GSHE MTJ elements 10(Buf).

In a preset mode 1, the pipeline stages 1 are preset to default logical values. Next, in a compute mode 1, charge currents 30(3) are provided to the GSHE MTJ elements 10(Buf) and the GSHE MTJ elements 10(Inv) in the pipeline stages 1 so that the GSHE MTJ elements 10(Buf) and the GSHE MTJ elements 10(Inv) perform their corresponding logical operations. The pipeline stage 1A is provided with the charge current 30(3) from a previous pipeline stage (not shown). The pipeline stage 1B is provided the charge current 30(3) from the pipeline stage 3A. The charge current 30(3) from the pipeline stage 3B is provided to a subsequent pipeline stage 1 (not shown). Bit states from the pipeline stages 3 are thus read in the compute mode 1 and the GSHE MTJ elements 10(Buf) and the GSHE MTJ elements 10(Inv) perform their respective logical operations by generating GSHE spin currents 22(1), which set bit states stored by the GSHE MTJ elements 10(Buf) and the GSHE MTJ elements 10(Inv) in the pipeline stages 1. The pipeline stages 2 provide isolation to the pipeline stages 1 and 3 during both the preset mode 1 and the compute mode 1.

In a preset mode 2, the pipeline stages 2 are preset to default logical values. Next, in a compute mode 2, charge currents 30(1) are provided to the GSHE MTJ elements 10(Inv) in the pipeline stages 2 so that the GSHE MTJ elements 10(Inv) perform their inversion operations. The pipeline stage 2A is provided with the charge current 30(1) from the pipeline stage 1A. The pipeline stage 2B is provided with the charge current 30(1) from the pipeline stage 1B. The bit states from the pipeline stages 1 are thus read in the compute mode 2 and the GSHE MTJ elements 10(Inv) perform their respective inversion operations by generating GSHE spin currents 22(2), which set bit states stored by the GSHE MTJ elements 10(Inv) in the pipeline stages 2. The pipeline stages 3 provide isolation to the pipeline stages 1 and 2 during both the preset mode 2 and the compute mode 2.

In a preset mode 3, the pipeline stages 3 are preset to default logical values. Next, in a compute mode 3, charge currents 30(2) are provided to the GSHE MTJ elements 10(Buf) and the GSHE MTJ elements 10(Inv) in the pipeline stages 3 so that the GSHE MTJ elements 10(Buf) and the GSHE MTJ elements 10(Inv) perform their corresponding logical operations. The pipeline stage 3A is provided with the charge current 30(2) from the pipeline stage 2A. The pipeline stage 3B is provided with the charge current 30(2) from the pipeline stage 2B. The bit states from the pipeline stages 2 are thus read in the compute mode 3 and the GSHE MTJ elements 10(Buf) and the GSHE MTJ elements 10(Inv) in the pipeline stages 3 perform their respective logical operations by generating GSHE spin currents 22(3), which set the bit states stored by the GSHE MTJ elements 10(Buf) and the GSHE MTJ elements 10(Inv) in the pipeline states 3. The pipeline stages 1 provide isolation between the pipeline stages 2 and 3 during both the preset mode 3 and the compute mode 3.

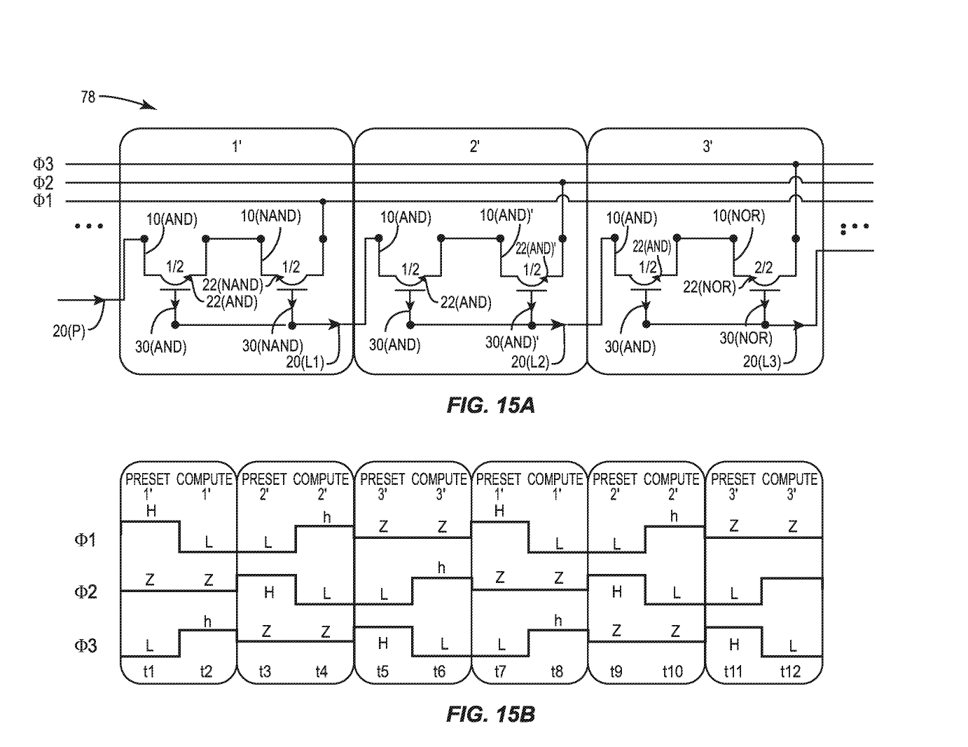

Referring now to FIGS. 15A and 15B, FIG. 15A illustrates one aspect of a pipeline circuit 78. The pipeline circuit 78 includes pipeline stage 1′, pipeline stage 2′, and pipeline stage 3′. Each of the pipeline stages 1′, 2′, and 3′ is configured to receive the control signal Φ1, the control signal Φ2, and the control signal Φ3 in order to synchronize the preset modes and the compute modes of the pipeline stage 3′. The pipeline stage 1′ includes one aspect of the GSHE MTJ element 10(AND) and one aspect of the GSHE MTJ element 10(NAND) described above with respect to FIG. 8. The pipeline stage 2′ includes one aspect of the GSHE MTJ element 10(AND) described above with respect to FIG. 8. The pipeline stage 2′ also includes an MTJ element 10(AND)′, which is also an aspect of the GSHE MTJ element 10(AND) described above with respect to FIG. 8. The pipeline stage 3′ includes one aspect of the GSHE MTJ element 10(NOR) and one aspect of the GSHE MTJ element 10(AND) described above with respect to FIG. 8.

Referring again to FIGS. 15A and 15B, FIG. 15B illustrates a timing diagram that represents the control state of the control signal Φ1, the control state of the control signal Φ2, and the control state of the control signal Φ3. In a preset mode 1′, the GSHE MTJ element 10(AND) and the GSHE MTJ element 10(NAND) in the pipeline stage 1′ are preset to their default logical values (i.e., logical “1” and logical “0,” respectively). Next, in a compute mode 1′, charge current 20(P) is provided to the GSHE MTJ element 10(AND) and the GSHE MTJ element 10(NAND) in the pipeline stage 1′. In response to the charge current 20(P), the GSHE MTJ element 10(AND) and the GSHE MTJ element 10(NAND) in the pipeline stage 1′ generate the GSHE spin current 22(AND) and the GSHE spin current 22(NAND), respectively. As such, the GSHE MTJ element 10(AND) and the GSHE MTJ element 10(NAND) in the pipeline stage 1′ each perform their corresponding logical operations. The pipeline stage 1′ is provided with the charge current 20(P) from a previous pipeline stage (not shown). Bit states from the previous pipeline stages are thus read in the compute mode 1′ and the GSHE MTJ element 10(AND) and the GSHE MTJ element 10(NAND) perform their respective logical operations. The pipeline stage 2′ provides isolation during both the preset mode 1′ and the compute mode 1′.

In a preset mode 2′, the GSHE MTJ element 10(AND) and the GSHE MTJ element 10(AND)′ in the pipeline stage 2′ are preset to their default logical values (i.e., logical “1” and logical “1,” respectively). Next, in a compute mode 2′, charge currents 30(AND) and 30(NAND) generated by the GSHE MTJ element 10(AND) and the GSHE MTJ element 10(NAND) in the pipeline stage 1′ are combined into a charge current 20(L1). The charge current 20(L1) is provided to the GSHE MTJ element 10(AND) and the GSHE MTJ element 10(AND)′ in the pipeline stage 2′ during the compute mode 2′. In response to the charge current 20(L1), the GSHE MTJ element 10(AND) and the GSHE MTJ element 10(AND)′ in the pipeline stage 2′ generate the GSHE spin current 22(AND) and a GSHE spin current 22(AND)′, respectively. As such, the GSHE MTJ element 10(AND) and the GSHE MTJ element 10(AND)′ in the pipeline stage 2′ each perform their corresponding logical operations. The bit states from the pipeline stage 1′ are thus read in the compute mode 2′ and the GSHE MTJ element 10(AND) and the GSHE MTJ element 10(AND)′ in the pipeline stage 2′ perform their respective logical operations. The pipeline stage 3′ provides isolation both in the preset mode 2′ and the compute mode 2′.

In a preset mode 3′, the GSHE MTJ element 10(NOR) and the GSHE MTJ element 10(AND) in the pipeline stage 3′ are preset to their default logical values (i.e., logical “0” and logical “0,” respectively). Next, in a compute mode 3′, the GSHE MTJ element 10(AND) in the pipeline stage 2′ generates the charge current 30(AND) and the GSHE MTJ element 10(AND)′ generates a charge current 30(AND)′, respectively. The charge current 30(AND) and the charge current 30(AND)′ from the pipeline stage 2′ are combined to provide a charge current 20(L2) to the pipeline stage 3′. In response to the charge current 20(L2), the GSHE MTJ element 10(NOR) and the GSHE MTJ element 10(AND) in the pipeline stage 3′ generate the GSHE spin current 22(NOR) and the GSHE spin current 22(AND), respectively, so as to perform their corresponding logical operations. The bit states from the pipeline stage 2′ are thus read and the GSHE MTJ element 10(AND) in the pipeline stage 3′ each perform their respective logical operations during the compute mode 3′. The pipeline stage 1′ provides isolation both in the preset mode 3′ and the compute mode 3′. Also, during the compute mode 1′, the GSHE MTJ element 10(NOR) and the GSHE MTJ element 10(AND) in the pipeline stage 3′ generate the charge currents 30(NOR) and 30(AND). The charge currents 30(NOR) and 30(AND) from the pipeline stage 3′ are combined into a charge current 20(L3) from the pipeline stage 3′. As such, the bit states from the pipeline stage 3′ are read during the compute mode 1′.

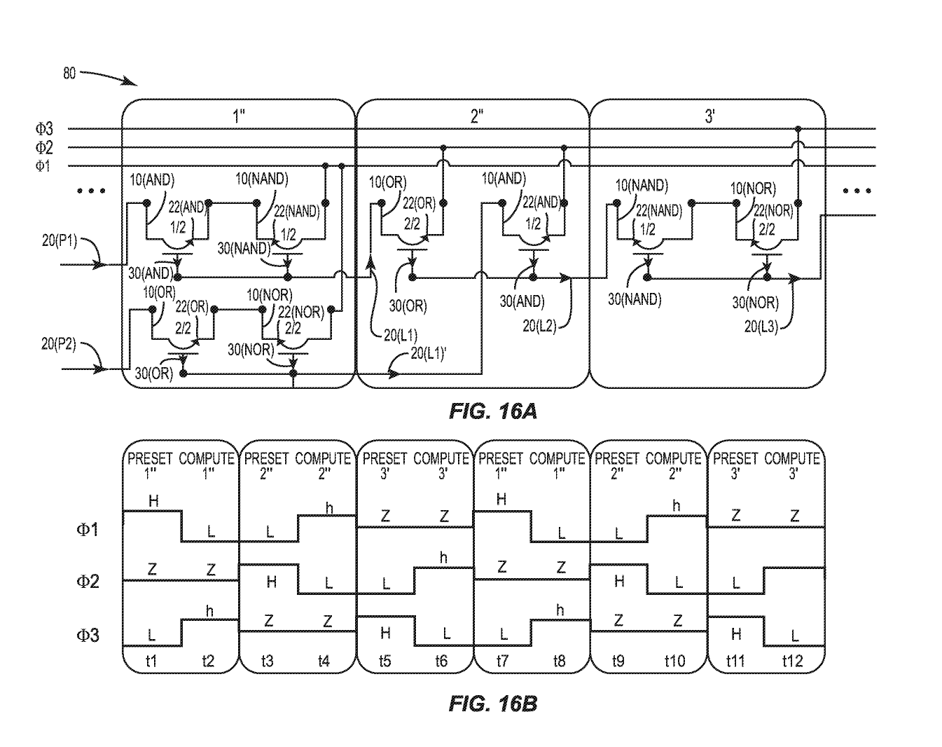

Referring now to FIGS. 16A and 16B, FIG. 16A illustrates one aspect of a pipeline circuit 80. The pipeline circuit 80 includes a pipeline stage 1″ and a pipeline stage 2″. The pipeline circuit 80 also includes the same aspect of the pipeline stage 3′ described above in FIG. 15A. The pipeline stages 1″, 2″, and 3′ of the pipeline circuit 80 are each configured to receive the control signal Φ1, the control signal Φ2, and the control signal Φ3 in order to synchronize the preset modes and the compute modes of each of the pipeline stages 1″, 2″, and 3′. The pipeline stage 1″ includes one aspect of the GSHE MTJ element 10(AND), one aspect of the GSHE MTJ element 10(NAND), one aspect of the GSHE MTJ element 10(OR), and one aspect of the GSHE MTJ element 10(NOR) described above with respect to FIG. 8. The pipeline stage 2″ includes one aspect of the GSHE MTJ element 10(OR) and one aspect of the GSHE MTJ element 10(AND) described above with respect to FIG. 8. The pipeline stage 3′ includes one aspect of the GSHE MTJ element 10(NOR) and one aspect of the GSHE MTJ element 10(NAND) described above with respect to FIG. 8.

Referring again to FIGS. 16A and 16B, FIG. 16B illustrates a timing diagram that represents the control state of the control signal Φ1, the control state of the control signal Φ2, and the control state of the control signal Φ3. The preset mode 3′ and the compute mode 3′ are the same as described above with respect to FIGS. 15A and 15B. In a preset mode 1″, the GSHE MTJ element 10(AND), the GSHE MTJ element 10(NAND), the GSHE MTJ element 10(OR), and the GSHE MTJ element 10(NOR) in the pipeline stage 1″ are preset to their default logical values (i.e., logical “1,” logical “0,” logical “1,” and logical “0,” respectively). Next, during a compute mode 1″, a charge current 20(P1) is provided to the GSHE MTJ element 10(AND) and the GSHE MTJ element 10(NAND) in the pipeline stage 1″. In response to the charge current 20(P1), the GSHE MTJ element 10(AND) and the GSHE MTJ element 10(NAND) in the pipeline stage 1″ generate the GSHE spin current 22(AND) and the GSHE spin current 22(NAND), respectively. In this manner, the GSHE MTJ element 10(AND) and the GSHE MTJ element 10(NAND) in the pipeline stage 1″ each perform their corresponding logical operations.

Additionally, a charge current 20(P2) is provided to the GSHE MTJ element 10(OR) and the GSHE MTJ element 10(NOR) in the pipeline stage 1″ during the compute mode 1″. In response to the charge current 20(P2), the GSHE MTJ element 10(OR) and the GSHE MTJ element 10(NOR) in the pipeline stage 1″ generate the GSHE spin current 22(OR) and the GSHE spin current 22(NOR), respectively. In this manner, the GSHE MTJ element 10(OR) and the GSHE MTJ element 10(NOR) in the pipeline stage 1″ each perform their corresponding logical operations. The pipeline stage 1″ is provided with the charge current 20(P1) and the charge current 20(P2) from previous pipeline stages (not shown). Bit states from the previous pipeline stages are thus read in the compute mode 1″ and the GSHE MTJ element 10(AND), the GSHE MTJ element 10(NAND), the GSHE MTJ element 10(OR), and the GSHE MTJ element 10(NOR) perform their respective logical operations.

In a preset mode 2″, the GSHE MTJ element 10(AND) and the GSHE MTJ element 10(OR) in the pipeline stage 2″ are preset to their default logical values (i.e., logical “1” and logical “1,” respectively). Next, in a compute mode 2″, the GSHE MTJ element 10(AND), the GSHE MTJ element 10(NAND), the GSHE MTJ element 10(OR), and the GSHE MTJ element 10(NOR) in the pipeline stage 1″ are configured to generate the charge currents 30(AND), 30(NAND), 30(OR), and 30(NOR), respectively. As such, the bit states from the pipeline stage 1″ are read during the compute mode 2″. The charge currents 30(AND) and 30(NAND) in the pipeline stage 1″ are combined into the charge current 20(L1). The charge currents 30(OR) and 30(NOR) in the pipeline stage 1″ are combined into the charge current 20(L1)′.

During the compute mode 2″, the charge current 20(L1) is provided to the GSHE MTJ element 10(OR) in the pipeline stage 2″. In response to the charge current 20(L1), the GSHE MTJ element 10(OR) in the pipeline stage 2″ is configured to generate the GSHE spin current 22(OR). As such, the GSHE MTJ element 10(OR) in the pipeline stage 2″ performs the OR operation during the compute mode 2″. Additionally, the charge current 20(L1)′ is provided to the GSHE MTJ element 10(AND) in the pipeline stage 2″. In response to charge current 20(L1)′, the GSHE MTJ element 10(AND) in the pipeline stage 2″ is configured to generate the GSHE spin current 22(AND). As such, the GSHE MTJ element 10(AND) in the pipeline stage 2″ performs the AND operation during the compute mode 2″. The pipeline stage 3′ provides isolation during both the preset mode 2″ and the compute mode 2″.

In the compute mode 3′, the GSHE MTJ element 10(OR) and the GSHE MTJ element 10(AND) in the pipeline stage 2″ are configured to generate the charge currents 30(OR) and 30(AND), respectively. As such, the bit states from the pipeline stage 2″ are read during the compute mode 3′. The charge currents 30(OR) and 30(AND) in the pipeline stage 2″ are combined into the charge current 20(L2). The operations of the pipeline stage 3′ are the same as described above with regard to FIGS. 15A and 15B and are illustrated in FIGS. 16A and 16B.

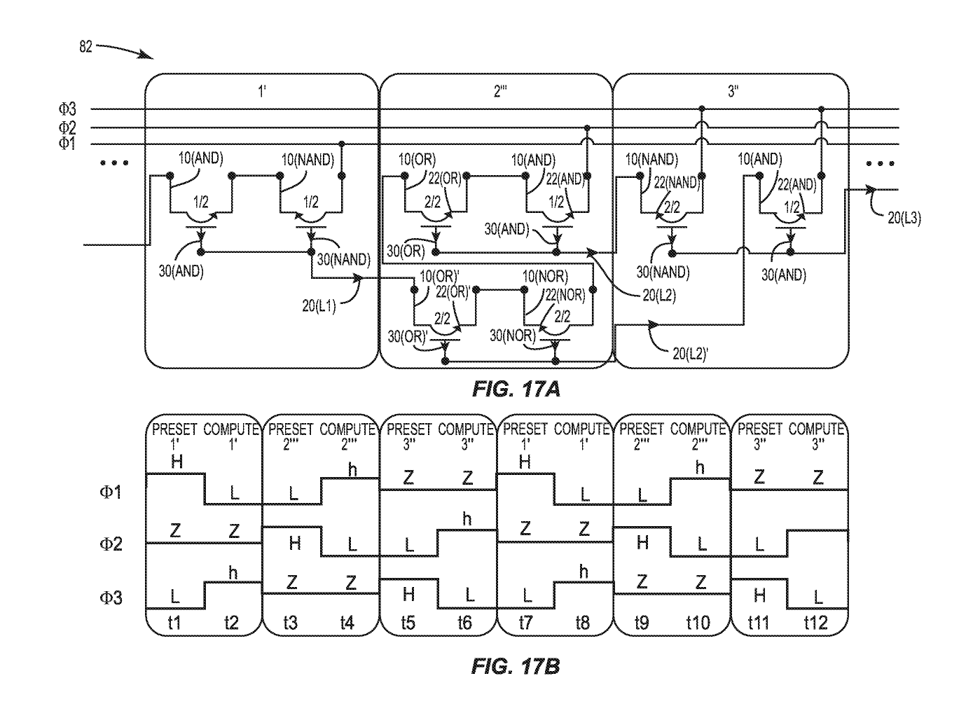

Referring now to FIGS. 17A and 17B, FIG. 17A illustrates one aspect of a pipeline circuit 82. The pipeline circuit 82 includes the pipeline stage 1′ described above with respect to FIG. 15A. The pipeline circuit 82 also includes a pipeline stage 2′″ and a pipeline stage 3″. The pipeline stages 1′, 2′″, and 3″ of the pipeline circuit 82 are each configured to receive the control signal Φ1, the control signal Φ2, the control signal Φ3 in order to synchronize the preset modes and the compute modes of each of the pipeline stages 1′, 2′″, and 3″. The pipeline stage 2′″ includes one aspect of the GSHE MTJ element 10(OR), one aspect of the GSHE MTJ element 10(AND), and one aspect of the GSHE MTJ element 10(NOR) described above with respect to FIG. 8. The pipeline stage 2′″ also includes one aspect of a MTJ element 10(OR)′, which is identical to the GSHE MTJ element 10(OR). The pipeline stage 3″ includes one aspect of the GSHE MTJ element 10(NAND) and one aspect of the GSHE MTJ element 10(AND) described above with respect to FIG. 8. As described above with respect to FIG. 15A, the pipeline stage 1′ includes one aspect of the GSHE MTJ element 10(AND) and one aspect of the GSHE MTJ element 10(NAND) described above with respect to FIG. 8.

Referring again to FIGS. 17A and 17B, FIG. 17B illustrates a timing diagram that represents the control state of the control signal Φ1, the control state of the control signal Φ2, and the control state of the control signal Φ3. The preset mode 1′ and the compute mode 1′ are the same as described above with respect to FIGS. 15A and 15B. During a preset mode 2′″, the GSHE MTJ element 10(OR), the GSHE MTJ element 10(AND), the GSHE MTJ element 10(OR)′, and the GSHE MTJ element 10(NOR) in the pipeline stage 2′″ are preset to their default logical values (i.e., logical “1,” logical “1,” logical “1,” and logical “0,” respectively). Next, in a compute mode 2′″, the GSHE MTJ element 10(AND) and the GSHE MTJ element 10(NAND) generate the charge current 20(L1). The charge current 20(L1) is provided to the GSHE MTJ element 10(OR), the GSHE MTJ element 10(AND), the GSHE MTJ element 10(OR)′, and the GSHE MTJ element 10(NOR) in the pipeline stage 2″. In response to the charge current 20(L1), the GSHE MTJ element 10(OR), the GSHE MTJ element 10(AND), the GSHE MTJ element 10(OR)′, and the GSHE MTJ element 10(NOR) in the pipeline stage 2′″ are configured to generate the GSHE spin current 22(OR), the GSHE spin current 22 (AND), a GSHE spin current 22(OR)′, and the GSHE spin current 22(NOR), respectively. As such, the GSHE MTJ element 10(OR), the GSHE MTJ element 10(AND), the GSHE MTJ element 10(OR)′, and the GSHE MTJ element 10(NOR) in the pipeline stage 2′″ perform their respective logical operations during the compute mode 2″. The bit states from the pipeline stage 1′ are thus read in the compute mode 2″. The pipeline stage 3′ provides isolation during both the preset mode 2′ and the compute mode 2″.

During a preset mode 3″, the GSHE MTJ element 10(NAND) and the GSHE MTJ element 10(AND) in the pipeline stage 3″ are preset to their default logical values (i.e., logical “0” and logical “1,” respectively). Next, in a compute mode 3″, the GSHE MTJ element 10(OR), the GSHE MTJ element 10(AND), the GSHE MTJ element 10(OR)′, and the GSHE MTJ element 10(NOR) in the pipeline stage 2′ generate the charge currents 30(OR), 30(NAND), and 30(NOR), and a charge current 30(OR)′ from the pipeline stage 2″. The charge currents 30(OR), 30(AND) are combined into the charge current 20(L2) from the pipeline stage 2″. The spin currents 30(OR)′ and 30(NOR) are combined into the charge current 20(L2)′ from the pipeline stage 2″. Additionally, the charge current 20(L2) is provided to the GSHE MTJ element 10(NAND) in the pipeline stage 3″ during the compute mode 3″. In response to charge current 20(L2), the GSHE MTJ element 10(NAND) in the pipeline stage 3″ is configured to generate the GSHE spin current 22(NAND). As such, the GSHE MTJ element 10(NAND) in the pipeline stage 3″ performs the NAND operation during the compute mode 3″. Additionally, the charge current 20(L2)′ is provided to the GSHE MTJ element 10(AND) in the pipeline stage 3″. In response to the charge current 20(L2)′, the GSHE MTJ element 10(AND) in the pipeline stage 3″ is configured to generate the GSHE spin current 22(AND). As such, the GSHE MTJ element 10(AND) in the pipeline stage 3″ performs the AND operation during the compute mode 3″. The pipeline stage 1′ provides isolation during both the preset mode 3″ and the compute mode 3″.

In the compute mode 1′, the GSHE MTJ element 10(NAND) and the GSHE MTJ element 10(AND) in the pipeline stage 3″ are configured to generate the charge currents 30(NAND) and 30(AND), respectively. As such, the bit states from the pipeline stage 3″ are read during the compute mode 1′. The charge currents 30(NAND) and 30(AND) in the pipeline stage 3″ are combined into the charge current 20(L3).

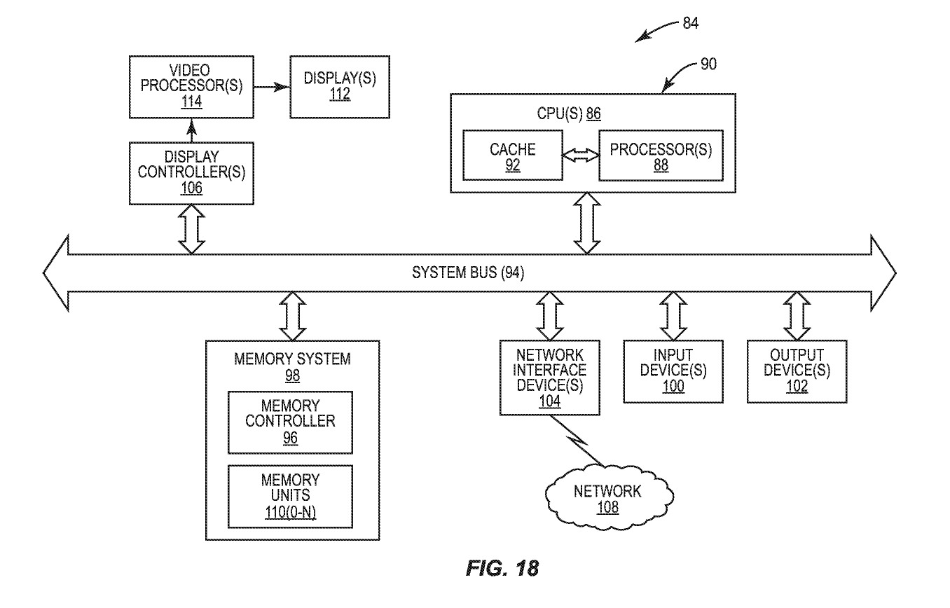

FIG. 18 is a block diagram of an exemplary processor-based system that can include the GSHE MTJ element 10, the spintronic logic gates 60, 68, 72, and 74, and the pipeline circuits 76, 78, 80, and 82 of FIGS. 1, 8, 11, 12, 13, 14A, 15A, 16A, and 17A.

The spintronic logic gates for performing logic operations, and related systems and methods according to aspects disclosed herein may be provided in or integrated into any processor-based device. Examples, without limitation, include a set top box, an entertainment unit, a navigation device, a communications device, a fixed location data unit, a mobile location data unit, a mobile phone, a cellular phone, a computer, a portable computer, a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, and a portable digital video player.

In this regard, FIG. 18 illustrates an example of a processor-based system 84 that can employ the GSHE MTJ element 10, the spintronic logic gates 60, 68, 72, and 74, and the pipeline circuits 76, 78, 80, and 82 of FIGS. 1, 8, 11, 12, 13, 14A, 15A, 16A, and 17A. In this example, the processor-based system 84 includes one or more central processing units (CPUs) 86, each including one or more processors 88. The CPU(s) 86 may be a master device 90. The CPU(s) 86 may have cache memory 92 coupled to the processor(s) 88 for rapid access to temporarily stored data. The CPU(s) 86 is coupled to a system bus 94 and can intercouple master and slave devices included in the processor-based system 84. As is well known, the CPU(s) 86 communicates with these other devices by exchanging address, control, and data information over the system bus 94. For example, the CPU(s) 86 can communicate bus transaction requests to the memory controller 96 as an example of a slave device. Although not illustrated in FIG. 18, multiple system buses 94 could be provided, wherein each system bus 94 constitutes a different fabric.

Other master and slave devices can be connected to the system bus 94. As illustrated in FIG. 18, these devices can include a memory system 98, one or more input devices 100, one or more output devices 102, one or more network interface devices 104, and one or more display controllers 106, as examples. The input device(s) 100 can include any type of input device, including but not limited to input keys, switches, voice processors, etc. The output device(s) 102 can include any type of output device, including but not limited to audio, video, other visual indicators, etc. The network interface device(s) 104 can be any devices configured to allow exchange of data to and from a network 108. The network 108 can be any type of network, including but not limited to a wired or wireless network, private or public network, a local area network (LAN), a wide local area network (WLAN), and the Internet. The network interface device(s) 104 can be configured to support any type of communication protocol desired. The memory system 98 can include one or more memory units 110(0-N).

The CPU(s) 86 may also be configured to access the display controller(s) 106 over the system bus 94 to control information sent to one or more displays 112. The display controller(s) 106 sends information to the display(s) 112 to be displayed via one or more video processors 114, which process the information to be displayed into a format suitable for the display(s) 112. The display(s) 112 can include any type of display, including but not limited to a cathode ray tube (CRT), a liquid crystal display (LCD), a plasma display, etc.

Those of skill in the art will further appreciate that the various illustrative logical blocks, modules, circuits, and algorithms described in connection with the aspects disclosed herein may be implemented as electronic hardware, instructions stored in memory or in another computer-readable medium and executed by a processor or other processing device, or combinations of both. The master devices, and slave devices described herein may be employed in any circuit, hardware component, integrated circuit (IC), or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flow chart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but is to be accorded the widest scope consistent with the principles and novel features disclosed herein.

What is claimed is:

1. A pipeline circuit, comprising:
a first pipeline stage comprising:
a first set of one or more magnetic tunnel junction (MTJ) elements configured to:
store a first bit set comprising one or more bit states for a first logical operation; and
generate a first charge current representing the first bit set; and
a second pipeline stage configured to receive the first charge current, wherein the second pipeline stage comprises a first Giant Spin Hall Effect (GSHE) MTJ element configured to set a first bit state for the first logical operation and having a first threshold current level, the first GSHE MTJ element being further configured to:
generate a first GSHE spin current in response to the first charge current; and
perform the first logical operation on the first bit set by setting the first bit state based on whether the first GSHE spin current exceeds the first threshold current level.

2. The pipeline circuit of claim 1, wherein:
the first set of one or more MTJ elements is configured to generate the first charge current representing the first bit set during a first compute mode; and
the first GSHE MTJ element is configured to generate the first GSHE spin current and perform the first logical operation during the first compute mode.

3. The pipeline circuit of claim 2, wherein the first GSHE MTJ element is further configured to preset the first bit state to a first logical value during a first preset mode prior to the first compute mode.

4. The pipeline circuit of claim 3, wherein the first GSHE MTJ element is configured to perform the first logical operation by being configured to:
maintain a first logical output bit state at the first logical value when the first GSHE spin current is below the first threshold current level; and
switch the first logical output bit state from the first logical value to a second logical value when the first GSHE spin current exceeds the first threshold current level, wherein the first logical value is antipodal with respect to the second logical value.

5. The pipeline circuit of claim 2 wherein:
the first set of one or more MTJ elements comprises a second GSHE MTJ element having a second threshold current level, wherein the second GSHE MTJ element is configured to:
store a second bit state for a second logical operation, wherein the one or more bit states of the first bit set includes the second bit state;
generate a second GSHE spin current in response to a second charge current representing a second bit set of the one or more bit states during a second compute mode; and
perform the second logical operation on the second bit set during the second compute mode by setting the second bit state based on whether the second GSHE spin current exceeds the second threshold current level.

6. The pipeline circuit of claim 5 further comprising a third pipeline stage wherein the third pipeline stage further comprises:
a second set of one or more MTJ elements configured to:
store the second bit set; and
generate the second charge current during the second compute mode.

7. The pipeline circuit of claim 6 wherein the third pipeline stage is configured to provide isolation during the first compute mode.

8. The pipeline circuit of claim 1 integrated into an integrated circuit (IC).

9. The pipeline circuit of claim 1 integrated into a device selected from the group consisting of a set top box, an entertainment unit, a navigation device, a communications device, a fixed location data unit, a mobile location data unit, a mobile phone, a cellular phone, a computer, a portable computer, a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, and a portable digital video player.

10. A pipeline method, comprising:
storing a first bit set comprising one or more bit states for a first logical operation with a first set of one or more magnetic tunnel junction (MTJ) elements within a first pipeline stage;
generating a first charge current representing the first bit set with the first set of one or more MTJ elements;
receiving the first charge current in a second pipeline stage, wherein the second pipeline stage comprises a first Giant Spin Hall Effect (GSHE) MTJ element configured to set a first bit state for the first logical operation and having a first threshold current level;
generating a first GSHE spin current with the first GSHE MTJ element in response to the first charge current; and
performing the first logical operation on the first bit set with the first GSHE MTJ element by setting the first bit state based on whether the first GSHE spin current exceeds the first threshold current level.

11. A spintronic logic gate, comprising:
a charge current generation circuit configured to generate a first charge current representing an input bit set comprising one or more input bit states for a first logical operation; and
a first Giant Spin Hall Effect (GSHE) magnetic tunnel junction (MTJ) element configured to set a first logical output bit state for the first logical operation and having a first threshold current level, the first GSHE MTJ element being further configured to:
generate a first GSHE spin current in response to the first charge current by producing a GSHE that converts the first charge current into the first GSHE spin current; and
perform the first logical operation on the input bit set by setting the first logical output bit state based on whether the first GSHE spin current exceeds the first threshold current level;
wherein the first GSHE MTJ element comprises a GSHE electrode configured to generate the first GSHE spin current in response to the first charge current.

12. The spintronic logic gate of claim 11, wherein the GSHE electrode has an electrode surface and the first GSHE MTJ element further comprises:
a first magnetic layer; and
a second magnetic layer having a magnetic layer surface disposed on the electrode surface such that the magnetic layer surface partially overlaps the electrode surface and an amount of the overlap between the magnetic layer surface and the electrode surface establishes the first threshold current level, wherein a tunneling barrier is defined between the second magnetic layer and the first magnetic layer.

13. The spintronic logic gate of claim 12, wherein the second magnetic layer is a free layer, the free layer having a magnetization switchable from a first magnetic orientation state to a second magnetic orientation state when the first GSHE spin current is above the first threshold current level, the first logical output bit state being represented by the first GSHE MTJ element based on the magnetization of the free layer.

14. The spintronic logic gate of claim 12, wherein a transverse expansion of the GSHE electrode sets the first threshold current level.

15. The spintronic logic gate of claim 11, further comprising a free layer having an easy axis, wherein an angle between a direction of propagation of the first charge current and the easy axis sets the first threshold current level.

16. The spintronic logic gate of claim 11 integrated into an integrated circuit (IC).

17. The spintronic logic gate of claim 11 integrated into a device selected from the group consisting of a set top box, an entertainment unit, a navigation device, a communications device, a fixed location data unit, a mobile location data unit, a mobile phone, a cellular phone, a computer, a portable computer, a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, and a portable digital video player.

18. A spintronic logic method, comprising:
generating a first charge current representing an input bit set comprising one or more input bit states for a first logical operation;
generating a first Giant Spin Hall Effect (GSHE) spin current with a GSHE electrode that provides a GSHE in response to the first charge current; and
performing the first logical operation on the input bit set by setting a first logical output bit state based on whether the first GSHE spin current exceeds a first threshold current level.
